(19) United States
(12) Patent Application Publication
(10) Pub. No.: US 2025/0240960 A1
(43) Pub. Date: Jul. 24, 2025

(54) SEMICONDUCTOR DEVICE, METHOD OF FABRICATING THE SAME, AND ELECTRONIC SYSTEM INCLUDING THE SAME

(71) Applicant: SAMSUNG ELECTRONICS CO., LTD., Suwon-si (KR)

(72) Inventors: Ju Mi Bak, Suwon-si (KR); So Young Shin, Suwon-si (KR); Seong Keun Cho, Suwon-si (KR); Song Yun Kang, Suwon-si (KR); Young Rok Kwon, Suwon-si (KR); Sung Gil Kim, Suwon-si (KR); Yihwan Kim, Suwon-si (KR); Jihye Lee, Suwon-si (KR)

(21) Appl. No.: 18/882,251

(22) Filed: Sep. 11, 2024

(30) Foreign Application Priority Data
Jan. 18, 2024 (KR) 10-2024-0007783

(51) Int. Cl. H10B 43/27; G11C 16/04; H01L 25/065; H10B 41/10; H10B 41/27; H10B 41/35; H10B 41/41; H10B 43/10; H10B 43/35; H10B 43/40; H10B 80/00

(52) U.S. Cl. CPC H10B 43/27; G11C 16/0483; H01L 25/0652; H10B 41/10; H10B 41/27; H10B 41/35; H10B 41/41; H10B 43/10; H10B 43/35; H10B 43/40; H10B 80/00; H01L 2225/06506

(57) ABSTRACT

A semiconductor device includes a first area and a second area around the first area, and comprises a source layer, a stack structure including a plurality of gate electrodes sequentially stacked and spaced apart from one another in a first direction, on the source layer, an interlayer insulating film covering the stack structure, a channel structure extending in the first direction extending into the stack structure in the first area and connected to the source layer in the first area, and a reflective structure overlapping in the first direction with the interlayer insulating film in the second area.

### CROSS-REFERENCE TO RELATED APPLICATION

This application claims priority to Korean Patent Application No. 10-2024-0007783 filed in the Korean Intellectual Property Office on Jan. 18, 2024, and all the benefits accruing therefrom under 35 U.S.C. 119, the contents of which are herein incorporated by reference in its entirety.

### BACKGROUND

As semiconductor memory devices capable of storing high-capacity data are required in electronic systems, methods to increase the data storage capacity of semiconductor memory devices are being researched. One of the methods to increase the data storage capacity of semiconductor memory devices proposes a semiconductor memory device including memory cells that are arranged three-dimensionally, instead of memory cells that are arranged two-dimensionally.

### SUMMARY

In general, in some aspects, the present disclosure is directed toward a semiconductor device and an electronic system including a semiconductor device with improved yield and reliability and a method of fabricating a semiconductor device, which can produce a semiconductor device with improved yield and reliability.

According to some implementations, the present disclosure is directed to a semiconductor device including a first area and a second area around the first area, comprising, a source layer, a stack structure including a plurality of gate electrodes, which are sequentially stacked by being spaced apart from one another in a first direction, on the source layer, an interlayer insulating film covering the stack structure, a channel structure extending in the first direction to penetrate the stack structure in the first area and be connected to the source layer in the first area, and a reflective structure overlapping in the first direction with the interlayer insulating film in the second area, wherein the reflective structure includes one or more first reflective layers, which have a first refractive index, and one or more second reflective layers, which are stacked alternating with the one or more first reflective layers in the first direction and have a second refractive index that is different from the first refractive index.

According to some implementations the present disclosure is directed to a semiconductor device semiconductor device comprising a peripheral circuit structure including a peripheral circuit substrate and a peripheral circuit element on the peripheral circuit substrate, and a memory cell structure stacked on the peripheral circuit structure and including a first area and a second area around the first area, wherein the memory cell structure includes a base insulating film, which has a first surface that faces the peripheral circuit structure and a second surface that is opposite to the first surface, a stack structure, which is on the first surface of the base insulating film and includes a plurality of gate electrodes that are sequentially stacked by being spaced apart from one another, an interlayer insulating film, which covers the stack structure, a source layer, which is on the second surface of the base insulating film, a channel structure, which intersects the plurality of gate electrodes in the first area and is connected to the source layer in the first area, and a reflective structure, which is interposed between the source layer in the second area and the interlayer insulating film in the second area, and the reflective structure includes one or more first reflective layers, which have a first refractive index and a first thickness, and one or more second reflective layers, which are stacked alternating with the one or more first reflective layers and have a second refractive index that is different from the first refractive index.

According to some implementations, the present disclosure is directed to a method of fabricating a semiconductor device, comprising providing a base layer including a first area and a second area around the first area, forming a reflective structure, which does not overlap with the first area and overlaps with the second area, on the base layer, forming a target layer on the base layer and the reflective structure, and performing a laser annealing process on the target layer, wherein the reflective structure includes one or more first reflective layers, which have a first refractive index, and one or more second reflective layers, which are stacked alternating with the one or more first reflective layers and have a second refractive index that is different from the first refractive index.

According to some implementations, the present disclosure is directed to an electronic system comprising a main substrate, a semiconductor memory device including a first area and a second area around the first area, on the main substrate, and a controller electrically connected to the semiconductor memory device, on the main substrate, wherein the semiconductor memory device includes a source layer, a stack structure, which includes a plurality of gate electrodes that are sequentially stacked by being spaced apart from one another in a first direction, on the source layer, an interlayer insulating film, which covers the stack structure, a channel structure, which extends in the first direction to penetrate the stack structure in the first area and be connected to the source layer in the first area, and a reflective layer, which overlaps in the first direction with the interlayer insulating film in the second area, and the reflective structure includes one or more first reflective layers, which have a first refractive index, and one or more second reflective layers, which are stacked alternating with the one or more first reflective layers in the first direction and have a second refractive index that is different from the first refractive index.

### BRIEF DESCRIPTION OF THE DRAWINGS

Example implementations will be more clearly understood from the following detailed description, taken in conjunction with the accompanying drawings.

FIG. 1 is a cross-sectional view showing an example of a semiconductor device according to some implementations.

FIGS. 2 through 6 are cross-sectional views showing an example of a method of fabricating a semiconductor device according to some implementations.

FIG. 7 is a block diagram showing a semiconductor device according to some implementations.

FIG. 8 is a circuit diagram showing an example of a semiconductor device according to some implementations.

FIGS. 9 and 10 are layout views showing an example of a semiconductor device according to some implementations.

FIG. 11 is a cross-sectional view taken along line A-A of FIG. 10 according to some implementations.

FIGS. 12A through 12E are enlarged cross-sectional views of examples of region R of FIG. 11 according to some implementations.

FIGS. 13 through 16 are cross-sectional views showing examples of semiconductor devices according to some implementations.

FIGS. 17 through 29 are cross-sectional views illustrating examples of intermediate steps of a method of fabricating a semiconductor device according to some implementations.

FIG. 30 is a block diagram showing an example of a n electronic system according to some implementations.

FIG. 31 is a perspective view showing an electronic system according to some implementations.

FIG. 32 is a cross-sectional view taken along line I-I of FIG. 31 according to some implementations.

### DETAILED DESCRIPTION

Hereinafter, example implementations will be explained in details with reference to the accompanying drawings. In the present disclosure, the term “identical” denotes not only completely the same but also encompasses the presence of minor differences that can occur due to process margins, etc. Furthermore, in the present disclosure, although terms such as “first,” “second,” etc., are used to describe various elements or components, these elements or components are not limited by these terms. These terms are used merely to distinguish one element or component from another. Accordingly, a first element or component mentioned below may also be a second element or component within the technical spirit of the disclosure.

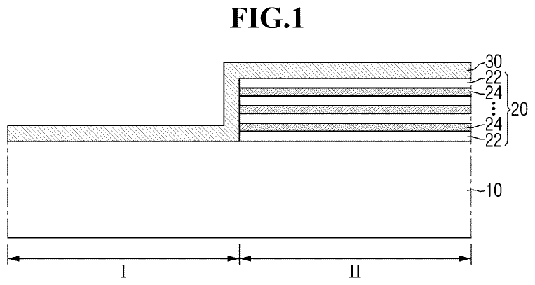

FIG. 1 is a cross-sectional view showing an example of a semiconductor device according to some implementations. In FIG. 1, a semiconductor device includes a base layer 10, a reflective structure 20, and a target layer 30. The base layer 10 may be provided as a substrate supporting the reflective structure 20 and the target layer 30. The base layer 10 may include a conductive material, such as a metal, a metal nitride, a metal silicide, or a metal silicide nitride film; an insulating material, such as silicon oxide, silicon nitride, or silicon oxynitride; or a semiconductor material, such as polysilicon, but the present disclosure is not limited thereto. For example, the base layer 10 may include a semiconductor substrate and multilayer metal wiring, which is formed on the semiconductor substrate.

The base layer 10 may include a first region I and a second region II, which are distinct from each other. The second region II may be disposed around the first region I. For example, the second region II may surround the perimeter of the first region I.

The reflective structure 20 may be formed on the second region II of the base layer 10. The reflective structure 20 may expose the first region I of the base layer 10. For example, the reflective structure 20 may not overlap with the first region I of the base layer 10 and may overlap with the second region II of the base layer 10. Here, the expression “overlap” denotes an overlap in a vertical direction perpendicular to the upper surface of the base layer 10.

The reflective structure 20 may include a distributed Bragg reflector (DBR). For example, the reflective structure 20 may have a multilayer structure in which one or more first reflective layers 22 and one or more second reflective layers 24 are alternately stacked. The first reflective layers 22 and the second reflective layers 24 may have different refractive indices. For example, the first reflective layers 22 may include a material, such as a silicon oxide film or a tetraethyl orthosilicate (TEOS) film, and the second reflective layers 24 may include a material, such as a silicon nitride film or a hafnium oxide film.

The reflective structure 20 is illustrated as including four first reflective layers 22 and three second reflective layers 24, but the present disclosure is not limited thereto. The numbers of first reflective layers 22 and second reflective layers 24 included in the reflective structure 20 may vary. Additionally, the first reflective layers 22 are illustrated as being disposed at uppermost and lowermost parts of the reflective structure 20, but the present disclosure is not limited thereto. In some implementations, the second reflective layers 24 may be disposed at the uppermost and lowermost parts of the reflective structure 20.

The reflective structure 20 is illustrated as being formed directly on the base layer 10, but the present disclosure is not limited thereto. In some implementations, there may exist another intervening layer or element between the base layer 10 and the reflective structure 20.

The target layer 30 may be formed on the base layer 10 and the reflective structure 20. For example, the target layer 30 may extend along the upper surface of the base layer 10, and along the sides and upper surface of the reflective structure 20. In some implementations, the target layer 30 may conformally extend along the profile of the upper surface of the base layer 10 and the sides and top of the reflective structure 20. The reflective structure 20 may be interposed between the second region II of the base layer 10 and the target layer 30.

The target layer 30 is illustrated as being formed directly on the base layer 10 and/or the reflective structure 20, but the present disclosure is not limited thereto. In some implementations, there may exist another intervening layer or element between the base layer 10 and the target layer 30 or between the reflective structure 20 and the target layer 30.

The target layer 30 may include a target material film to be subject to a laser annealing process. For example, the target layer 30 may include a semiconductor material film, such as a polysilicon film. In some implementations, the target layer 30 may include an impurity-doped polysilicon film.

An example of a method of fabricating a semiconductor device according to some implementations will hereinafter be described with reference to FIGS. 1 through 6.

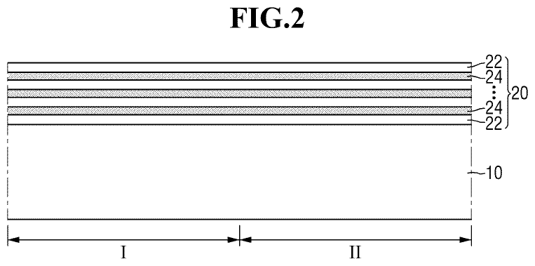

FIGS. 2 through 6 are cross-sectional views showing an example of a method of fabricating a semiconductor device according to some implementations. For convenience, descriptions of content overlapping with what has been described so far with reference to FIG. 1 will be simplified or omitted.

In FIG. 2, a reflective structure 20 is formed on a base layer 10. The reflective structure 20 may cover a first region I and a second region II of the base layer 10. The reflective structure 20 may have a multilayer structure in which one or more first reflective layers 22 and one or more second reflective layers 24 are alternately stacked. The first reflective layers 22 and the second reflective layers 24 may be formed by a chemical vapor deposition (CVD) method or an atomic layer deposition (ALD) method, but the present disclosure is not limited thereto.

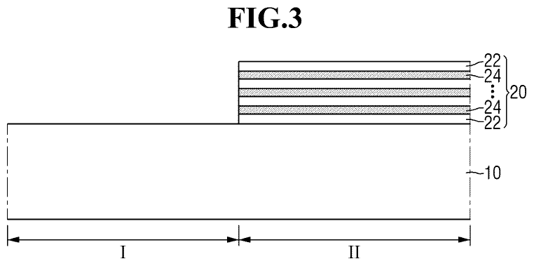

In FIG. 3, the reflective structure 20 is patterned. For example, a photolithography process for the reflective structure 20 may be performed. As a result, a reflective structure 20 that exposes the first region I of the base layer 10 may be formed.

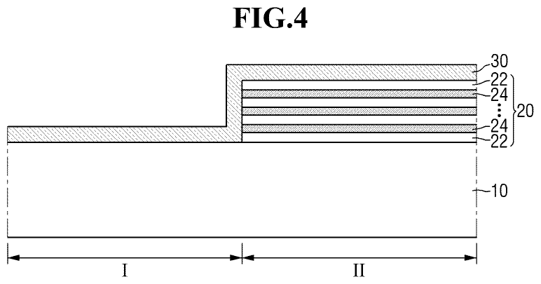

In FIG. 4, a target layer 30 is formed on the base layer 10 and the reflective structure 20. The target layer 30 may cover the base layer 10 and the reflective structure 20. For example, the target layer 30 may extend along the upper surface of the base layer 10, and along the sides and upper surface of the reflective structure 20.

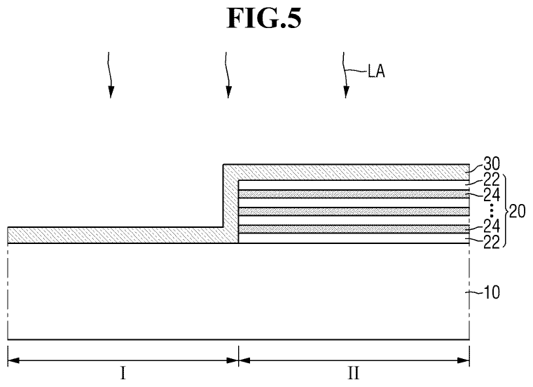

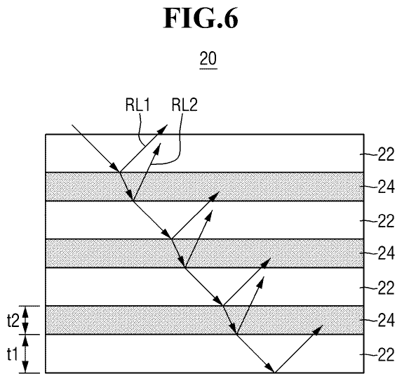

In FIGS. 5 and 6, a laser annealing process LA is performed on the target layer 30. As the laser annealing process LA is performed, crystallization of the target layer 30 may be induced or the properties of the material included in the target layer 30 may be improved. For example, if the target layer 30 includes a polysilicon film doped with impurities, the laser annealing process LA can increase the grain size of the target layer 30 or can enhance the electrical properties of the target layer 30 by activating the doped impurities.

In some implementations, the laser annealing process LA may use visible laser light. For example, a wavelength λ of laser light used in the laser annealing process LA may be about 400 nm to about 700 nm.

In some implementations, the energy density of the laser light used in the laser annealing process LA may be about 50 mJ/cm² to about 2,000 mJ/cm². In some implementations, the energy density of the laser light used in the laser annealing process LA may be about 200 mJ/cm² to about 1,200 mJ/cm².

In the laser annealing process LA, the reflective structure 20 may utilize Fresnel reflection enhancement interference to provide high reflectivity and low transmittance. For example, as illustrated in FIG. 6, the reflective structure 20 may include the first reflective layers 22 and the second reflective layers 24, which are stacked alternating with the first reflective layers 22. A first refractive index of the first reflective layers 22 may be lower than a second refractive index of the second reflective layers 24. For example, each of the first reflective layers 22 may include a silicon oxide film, and each of the second reflective layers 24 may include a silicon nitride film. In this example, first reflected light RL1 occurring at the surfaces (e.g., the upper surface) of the second reflective layers 24 may create constructive interference with second reflected light RL2 occurring at the surfaces (e.g., the upper surfaces) of the first reflective layers 22. Consequently, the reflective structure 20 can selectively block the laser light entering the second region II of the base layer 10.

To induce such constructive interference, a first thickness t₁ of the first reflective layers 22 and a second thickness t₂ of the second reflective layers 24 may be appropriately selected based on the wavelength of the laser light used in the laser annealing process LA. For example, if the first refractive index of the first reflective layers 22 is lower than the second refractive index of the second reflective layers 24, the first thickness t₁ of the first reflective layers 22 may be greater than the second thickness t₂ of the second reflective layers 24.

In some implementations, the first thickness t₁ of the first reflective layers 22 may be selected within the range defined by Equation (1) below, and the second thickness t₂ of the second reflective layers 24 may be selected within the range defined by Equation (2) below.

$$\frac{λ}{4 {n}_{1}} - Δ {t}_{1} \leq {t}_{1} \leq \frac{λ}{4 {n}_{1}} + Δ {t}_{1} ( where Δ {t}_{1} = \frac{1}{10} ( \frac{λ}{4 {n}_{1}} ) ) \qquad ( 1 )$$

$$\frac{λ}{4 {n}_{2}} - Δ {t}_{2} \leq {t}_{2} \leq \frac{λ}{4 {n}_{2}} + Δ {t}_{2} ( where Δ {t}_{2} = \frac{1}{10} ( \frac{λ}{4 {n}_{2}} ) ) \qquad ( 2 )$$

In Equations (1) and (2), λ represents the wavelength of light (particularly, laser light) irradiated onto the reflective structure 20 during the laser annealing process LA, n₁ represents the first refractive index of the first reflective layers 22, and n₂ represents the second refractive index of the second reflective layers 24.

For example, the wavelength A of the laser light used in the laser annealing process LA may be about 532 nm. At the wavelength 2, the first refractive index n₁ of the first reflective layers 22, which include silicon oxide, may be about 1.46, and the second refractive index n₂ of the second reflective layers 24, which include silicon nitride, may be about 2.02. In this example, the first thickness t₁ of the first reflective layers 22 may range from about 82 nm to about 100 nm, and the second thickness t₂ of the second reflective layers 24 may be about 60 nm to about 72 nm.

In some implementations, the reflective structure 20 may include at least three pairs of the first reflective layers 22 and the second reflective layers 24. Accordingly, constructive interference can be effectively induced.

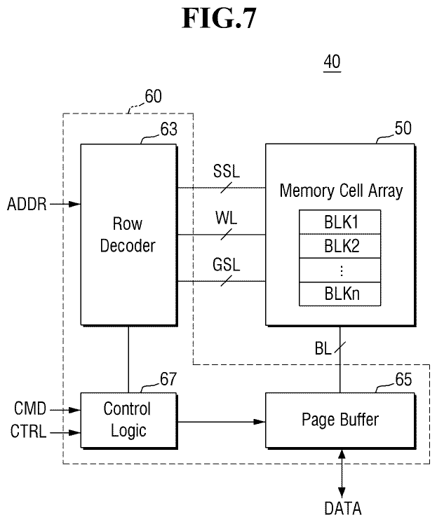

An example of a semiconductor device according to some implementations of the present disclosure will hereinafter be described with reference to FIGS. 7 through 16. In the following description, the semiconductor device will be described, taking a NAND flash memory device as an example, but the present disclosure is not limited thereto. In some implementations, the semiconductor device may also be another type of non-volatile memory device, such as a phase-change random access memory (PRAM), a magnetoresistive random access memory (MRAM), a ferroelectric random access memory (FeRAM), or a resistive random access memory (RRAM), a volatile memory device, such as a dynamic random access memory (DRAM) or a static random access memory (SRAM), or a logic device, such as a central processing unit (CPU), a graphics processing units (GPU), a controller, an application-specific integrated circuit (ASIC), or an application processor (AP).

FIG. 7 is a block diagram showing an example of a semiconductor device according to some implementations. In FIG. 7, a memory cell array 50 may include a plurality of memory cell blocks BLK1 through BLKn. Each of the memory cell blocks BLK1 through BLKn may include a plurality of memory cells. The memory cell array 50 may be connected to peripheral circuitry 60 through bitlines BL, wordlines WL, one or more string select lines SSL, and one or more ground select lines GSL. Specifically, the memory cell blocks BLK1 through BLKn may be connected to a row decoder 63 through the wordlines WL, the string select lines SSL, and the ground select lines GSL. Additionally, the memory cell blocks BLK1 through BLKn may be connected to a page buffer 65 through the bitlines BL.

The peripheral circuitry 60 may receive addresses ADDR, commands CMD, and control signals CTRL from outside the semiconductor device 40 and may exchange data DATA with an external device outside the semiconductor device 40. The peripheral circuitry 60 may include control logic 67, the row decoder 63, and the page buffer 65. Additionally, the peripheral circuitry 60 may further include various sub-circuits, such as an input/output circuit, a voltage generation circuit that generates various voltages required for the operation of the semiconductor device 40, and/or an error correction circuit that corrects error in the data DATA read from the memory cell array 50.

The control logic 67 may be connected to the row decoder 63, the input/output circuit, and the voltage generation circuit. The control logic 67 may control the overall operation of the semiconductor device 40. The control logic 67 may generate various internal control signals for use in the semiconductor device 40 in response to the control signals CTRL. For example, the control logic 67 may adjust the voltage level to be provided to the wordlines WL and the bitlines BL during a memory operation such as programming or erasing.

In response to the addresses ADDR, the row decoder 63 may select at least one of the memory cell blocks BLK1 through BLKn, and may choose at least one wordline WL, at least one string select line SSL, and at least one ground select line GSL from the selected memory cell block(s). Furthermore, the row decoder 63 may deliver voltages to the wordlines WL of the selected memory cell block(s) for performing a memory operation.

The page buffer 65 may be connected to the memory cell array 50 through the bitlines BL. The page buffer 65 may operate as a write driver or a sense amplifier. For example, during a program operation, the page buffer 65 operates as a write driver, applying a voltage corresponding to the data DATA to be stored in the memory cell array 50 to the bitlines BL. Conversely, during a read operation, the page buffer 65 operates as a sense amplifier, detecting the data DATA stored in the memory cell array 50.

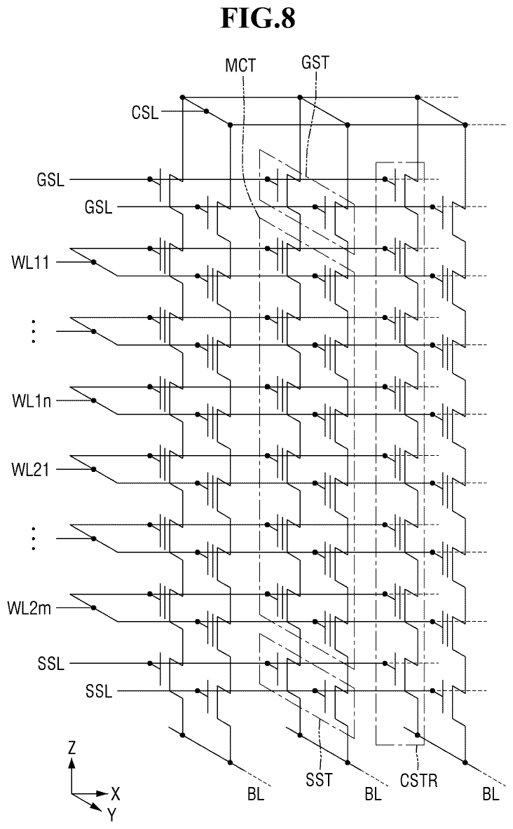

FIG. 8 is a circuit diagram showing an example of a semiconductor device according to some implementations. In FIG. 8, a memory cell array (e.g., the memory cell array 50 of FIG. 7) of the semiconductor device according to some embodiments of the present disclosure includes a common source line CSL, a plurality of bitlines BL, and a plurality of cell strings CSTR.

The bitlines BL may be arranged two-dimensionally in a plane including first and second directions X and Y. For example, the bitlines BL may extend in the second direction Y and may be spaced apart from one another along the first direction X. The cell strings CSTR may be connected in parallel to the bitlines BL. The cell strings CSTR may be connected in common to the common source line CSL. That is, the cell strings CSTR may be disposed between the bitlines BL and the common source line CSL.

Each of the cell strings CSTRs may include a ground select transistor GST, which is connected to the common source line CSL, a string select transistor SST, which is connected to the bitlines BL, and a plurality of memory cell transistors MCT, which are disposed between the ground select transistor GST and the string select transistor SST. Each of the memory cell transistors MCT may include a data storage element. The ground select transistor GST, the string select transistor SST, and the memory cell transistors MCT may be connected in series in a third direction Z, which intersects the first and second directions X and Y.

The common source line CSL may be connected in common to the sources of the ground select transistors GST. Additionally, the ground select lines GSL, a plurality of wordlines (WL11 through WLIn and WL21 through WL2m), and the string select lines SSL may be disposed between the common source line CSL and the bitlines BL. The ground select line GSL may serve as the gate electrodes of the ground select transistors GST, wordlines WL1 through WLn may serve as the gate electrodes of the memory cell transistors MCT, and the string select lines SSL may serve as the gate electrodes of the string select transistors SST.

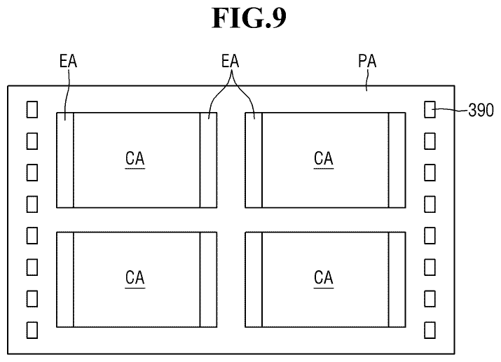

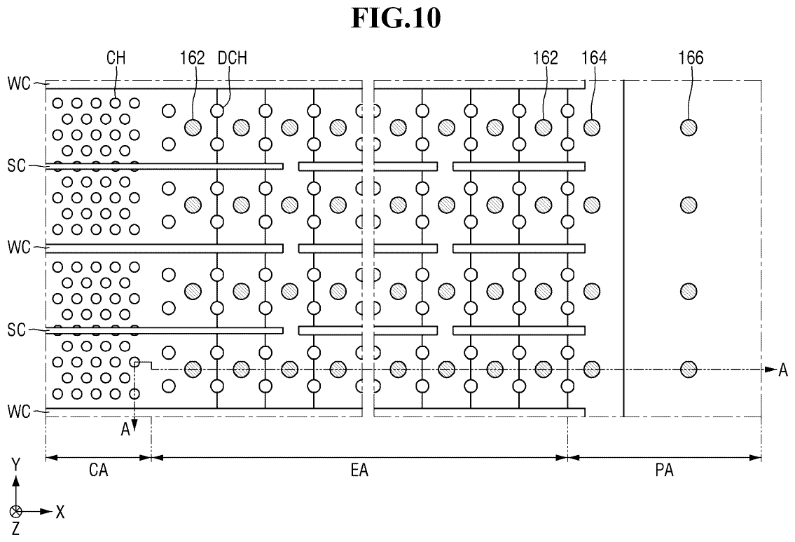

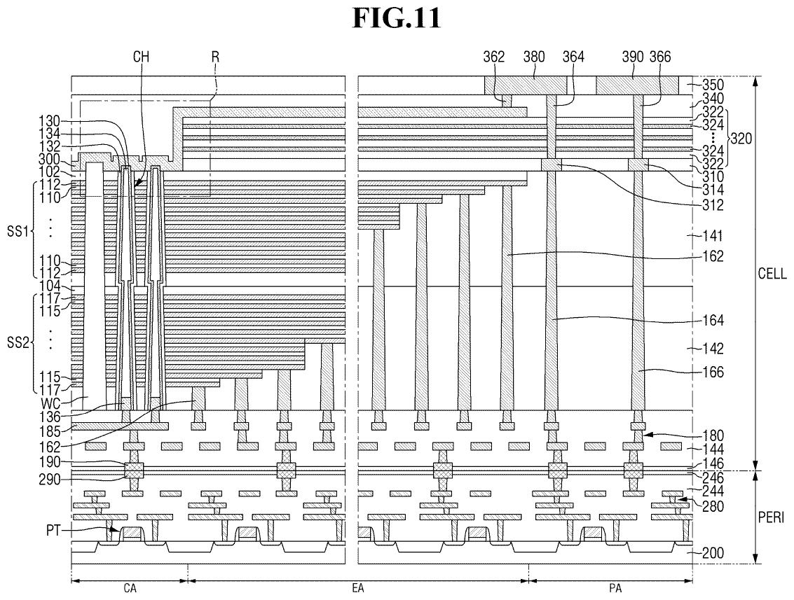

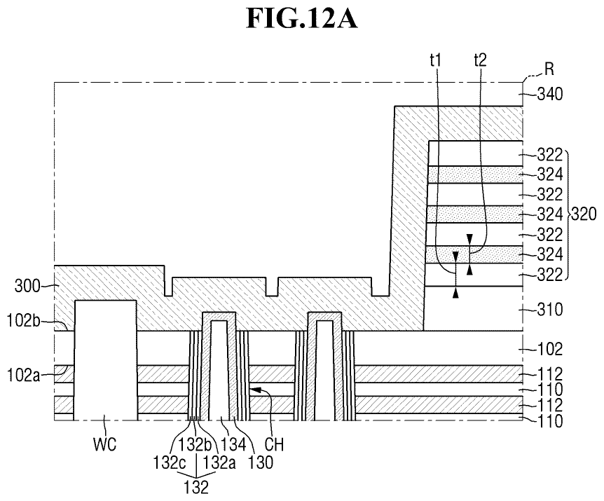

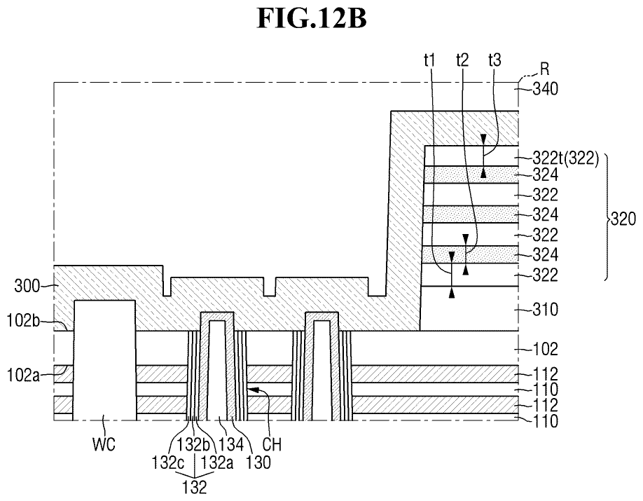

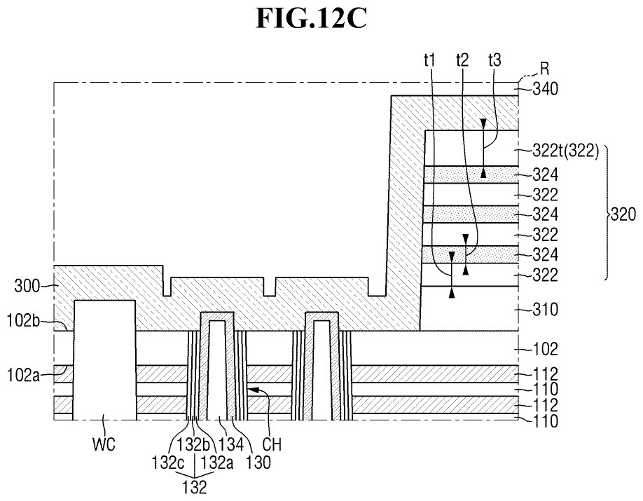

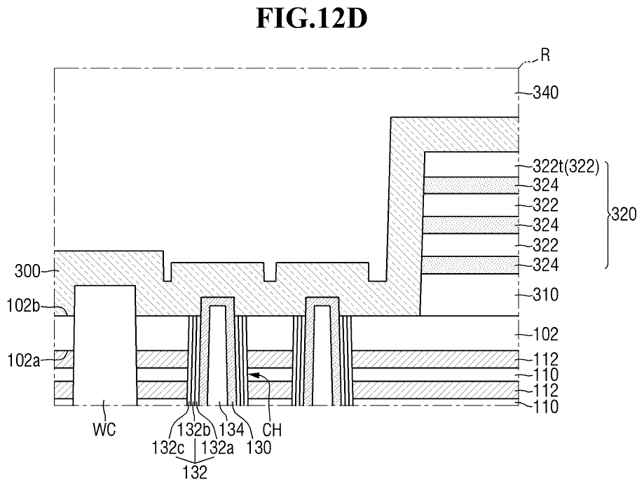

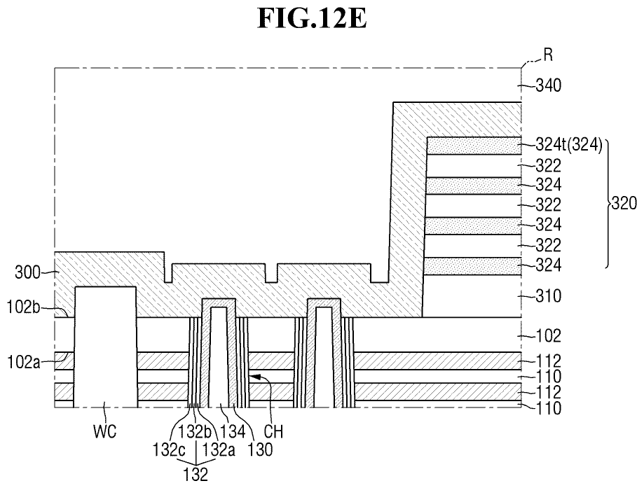

FIGS. 9 and 10 are layout views showing an example of a semiconductor device according to some implementations. FIG. 11 is a cross-sectional view taken along line A-A of FIG. 10 according to some implementations. FIGS. 12A through 12E are enlarged cross-sectional views of examples of region R of FIG. 11 according to some implementations.

In FIGS. 9 through 12A, the semiconductor device includes a memory cell structure CELL and a peripheral circuit structure PERI. The memory cell structure CELL may include cell array areas CA, extension areas EA, and an external area PA.

In each of the cell array areas CA, a memory cell array (e.g., the memory cell array 50 of FIG. 7) including a plurality of memory cells may be formed. For example, channel structures CH, gate electrodes (112 and 117), conductive lines 185, and a source layer 300 may be disposed in each of the cell array areas CA.

The extension areas EA may be disposed around the cell array areas CA. For example, the extension areas EA may be adjacent to the cell array areas CA in a first direction X. In each of the extension areas EA, the gate electrodes (112 and 117) that will be described below may be stacked in a stepwise fashion.

The external area PA may be a surrounding area encircling the cell array areas CA and the extension areas EA. For example, the external area PA may be adjacent to the cell array areas CA and/or the extension areas EA in the first direction X and/or a second direction Y. Conductive pads 390 that will be described later may be disposed in the external area PA.

The memory cell structure CELL may include a first base insulating film 102, a first stack structure SS1, a first interlayer insulating film 141, a second base insulating film 104, a second stack structure SS2, a second interlayer insulating film 142, the channel structures CH, cutting patterns WC, gate contacts 162, source contacts 164, through vias 166, cell wiring structures 180, the source layer 300, an upper insulating film 310, a reflective structure 320, a third interlayer insulating film 340, a fourth interlayer insulating film 350, connection patterns 380, and the conductive pads 390.

The first base insulating film 102 may form an insulating area across the cell array area CA and the extension areas EA. The first base insulating film 102 may include at least one of silicon oxide, silicon nitride, and silicon oxynitride, but the present disclosure is not limited thereto. For example, the first base insulating film 102 may include a silicon oxide film.

The first base insulating film 102 may have first and second surfaces 102a and 102b, which are opposite to each other. The first and second surfaces 102a and 102b may extend along a horizontal plane (e.g., an XY plane).

The first stack structure SS1 may be formed on the first surface 102a of the first base insulating film 102. The first stack structure SS1 may include a plurality of first mold insulating films 110 and a plurality of first gate electrodes 112, which are stacked on the first base insulating film 102 alternating with the first mold insulating films 110. The first mold insulating films 110 and the first gate electrodes 112 may form a layered structure extending along the horizontal plane (for example, the XY plane). The first gate electrodes 112 may be sequentially stacked by being spaced apart from one another by the first mold insulating films 110.

In each of the extension areas EA, the first gate electrodes 112 may be stacked in a stepwise fashion on the first base insulating film 102. For example, in each of the extension areas EA, the extension length in the first direction X, of the first gate electrodes 112 may decrease away from the first base insulating film 102.

In some implementations, the first gate electrodes 112 may include one or more ground select lines (“GSL” of FIG. 8) and a plurality of first wordlines (“WL11” through “WL1n” of FIG. 8), which are sequentially stacked on the first base insulating film 102. The numbers and shapes of the first mold insulating films 110 and the first gate electrodes 112 are merely example and are not particularly limited.

The first interlayer insulating film 141 may be formed on the first base insulating film 102 and the first stack structure SS1. The first interlayer insulating film 141 may cover the first base insulating film 102 and the first stack structure SS1. The first interlayer insulating film 141 may include, for example, at least one of silicon oxide, silicon nitride, silicon oxynitride, and a low-k material with a smaller dielectric constant than silicon oxide, but the present disclosure is not limited thereto.

The second base insulating film 104 may be formed on the first interlayer insulating film 141. The second base insulating film 104 may form an insulating area across the cell array areas CA and the extension areas EA. The second base insulating film 104 may include, for example, at least one of silicon oxide, silicon nitride, and silicon oxynitride, but the present disclosure is not limited thereto. For example, the second base insulating film 104 may include a silicon oxide film.

The second stack structure SS2 may be formed on the second base insulating film 104. The second stack structure SS2 may include a plurality of second mold insulating films 115 and a plurality of second gate electrodes 117, which are stacked on the second base insulating film 104 alternating with the second mold insulating films 115. The second mold insulating films 115 and the second gate electrodes 117 may form a layered structure extending along the horizontal plane (e.g., the XY plane). The second gate electrodes 117 may be sequentially stacked by being spaced apart from one another by the second mold insulating films 115.

In each of the extension areas EA, the second gate electrodes 117 may be stacked on the second base insulating film 104 in a stepwise fashion. For example, in each of the extension areas EA, the extension length in the first direction X, of the second gate electrodes 117 may decrease away from the second base insulating film 104.

In some implementations, the second gate electrodes 117 may include a plurality of second wordlines (e.g., the wordlines WL21 through WL2m of FIG. 8), which are sequentially stacked on the second base insulating film 104, and one or more string select lines (e.g., the string select lines SSL of FIG. 8). The numbers and shapes of the second mold insulating films 115 and the second gate electrodes 117 are merely example and are not particularly limited.

The second interlayer insulating film 142 may be formed on the second base insulating film 104 and the second stack structure SS2. The second interlayer insulating film 142 may cover the second base insulating film 104 and the second stack structure SS2. The second interlayer insulating film 142 may include, for example, at least one of silicon oxide, silicon nitride, silicon oxynitride, and a low-k material with a smaller dielectric constant than silicon oxide, but the present disclosure is not limited thereto.

The gate electrodes (112 and 117) may include a conductive material, for example, a metal, such as tungsten (W), molybdenum (Mo), ruthenium (Ru), cobalt (Co), or nickel (Ni), or a semiconductor material, such as silicon (Si), but the present disclosure is not limited thereto. For example, the gate electrodes (112 and 117) may contain at least one of W, Mo, and Ru. In another example, the gate electrodes (112 and 117) may contain polysilicon.

Mold insulating films (110 and 115) may include, for example, at least one of silicon oxide, silicon nitride, and silicon oxynitride, but the present disclosure is not limited thereto. For example, the mold insulating films (110 and 115) may include a silicon oxide film.

The channel structures CH may be disposed in the cell array areas CA. The channel structures CH may extend in a third direction Z, penetrating the first and second stack structures SS1 and SS2. The channel structures CH may intersect the gate electrodes (112 and 117). For example, the channel structures CH may be in the shape of pillars (e.g., cylinders) extending in the third direction Z.

In some implementations, the channel structures CH may be arranged in a zigzag fashion. As illustrated in FIG. 10, the channel structures CH may be staggered in the first and second directions X and Y. The channel structures CH can enhance the integration density of the semiconductor device. The number and arrangement of channel structures CH are merely example and are not particularly limited.

In some implementations, each of the channel structures CH may have a step difference between the first stack structure SS1 and the second stack structure SS2. For example, as illustrated in FIG. 11, the sides of each of the channel structures CH may have a bending portion at the boundary between the first interlayer insulating film 141 and the second base insulating film 104. The channel structures CH may include semiconductor films 130 and data storage films 132.

The semiconductor films 130 may extend in the third direction Z and may intersect the gate electrodes (112 and 117). The semiconductor films 130 are illustrated as being cup-shaped, but the present disclosure is not limited thereto. In some implementations, the semiconductor films 130 may have various other geometric shapes, such as a cylindrical, rectangular prism, or filled pillar shape. The semiconductor films 130 may include, for example, monocrystalline silicon, polycrystalline silicon, an organic semiconductor, and carbon nanostructures, but the present disclosure is not limited thereto.

The data storage films 132 may be interposed between the semiconductor films 130 and the gate electrodes (112 and 117). For example, the data storage films 132 may extend along the outer side surfaces of the semiconductor films 130. The data storage films 132 may include, for example, at least one of silicon oxide, silicon nitride, silicon oxynitride, and a high-k material with a greater dielectric constant than silicon oxide, but the present disclosure is not limited thereto. The high-k material may include, for example, at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

In some implementations, the data storage films 132 may be formed as multilayers. For example, as illustrated in FIG. 12A, each of the data storage films 132 may include a tunnel insulating film 132a, a charge storage film 132b, and a blocking insulating film 132c, which are sequentially stacked on the outer side surfaces of the corresponding semiconductor film 130.

The tunnel insulating films 132a may include, for example, silicon oxide or a high-k material with a greater dielectric constant than silicon oxide (e.g., aluminum oxide (Al₂O₃) or hafnium oxide (HfO₂)). The charge storage films 132b may include, for example, silicon nitride. The blocking insulating films 132c may include, for example, silicon oxide or a high-k material with a greater dielectric constant than silicon oxide (e.g., Al₂O₃ or HfO₂).

In some implementations, the channel structures CH may further include fill insulating films 134. The fill insulating films 134 may be formed to fill the inside of the cup-shaped semiconductor films 130. The fill insulating films 134 may include, for example, an insulating material, such as silicon oxide, but the present disclosure is not limited thereto.

In some implementations, the channel structures CH may further include channel pads 136. The channel pads 136 may be formed to be connected to ends (e.g., lower ends) of the semiconductor films 130. The channel pads 136 may contain a conductive material, such as doped polysilicon, a metal, or a metal silicide, but the present disclosure is not limited thereto.

In some implementations, dummy channel structures DCH may be formed within the extension areas EA. The dummy channel structures DCH may extend in the third direction Z, penetrating at least parts of the first and second stack structures SS1 and SS2.

The dummy channel structures DCH may be formed at the same level as or at a different level from the channel structures CH. For example, if formed at the same level as the channel structures CH, the dummy channel structures DCH may also include the semiconductor films 130, the data storage films 132, the fill insulating films 134, and the channel pads 136. In some implementations, if formed at a different level from the channel structures CH, the dummy channel structures DCH may be filled with an insulating material and/or a conductive material. The size (e.g., width) of the dummy channel structures DCH may be the same as or different from the size of the channel structures CH. In some implementations, the size of the dummy channel structures DCH may be greater than the size of the channel structures CH.

The cutting patterns WC may be formed across the cell array areas CA and the extension areas EA. The cutting patterns WC may extend longitudinally in the first direction X to cut the first and second stack structures SS1 and SS2. Moreover, the cutting patterns WC may be spaced apart from one another in the second direction Y, extending in parallel in the first direction X. The first and second stack structures SS1 and SS2 may be divided by the cutting patterns WC, thereby forming a plurality of memory cell blocks (e.g., the memory cell blocks BLK1 through BLKn of FIG. 7). For example, two adjacent cutting patterns WC may define a single memory cell block therebetween. Multiple channel structures CH may be disposed in each of the memory cell blocks defined by the cutting patterns WC.

In some implementations, the cutting patterns WC may include an insulating material, for example, at least one of silicon oxide, silicon nitride, and silicon oxynitride, but the present disclosure is not limited thereto. For example, the cutting patterns WC may include a silicon oxide film.

In some implementations, separation patterns SC may be formed within the second stack structure SS2. The separation patterns SC may extend in the first direction X, cutting the string select lines (e.g., the string select lines SSL of FIG. 8) of the second stack structure SS2, for example, the lowermost second gate electrodes 117. Each of the memory cell blocks defined by the cutting patterns WC may be divided by the separation patterns SC to form multiple string areas. For example, one separation pattern SC may define two string areas within a single memory cell block. The separation patterns SC may include an insulating material, for example, at least one of silicon oxide, silicon nitride, and silicon oxynitride, but the present disclosure is not limited thereto.

The gate contacts 162 may be disposed in the extension areas EA. The gate contacts 162 may be electrically connected to the corresponding gate electrodes (112 and 117). For example, the gate contacts 162 may extend in the third direction Z, penetrating the first interlayer insulating film 141 and/or the second interlayer insulating film 142, and may be connected to the corresponding gate electrodes (112 and 117). In some implementations, the width of the gate contacts 162 may decrease closer to the gate electrodes (112 and 117).

The source contacts 164 and the through vias 166 may be disposed in the external area PA. The source contacts 164 and the through vias 166 may extend in the third direction Z, penetrating the first interlayer insulating film 141 and/or the second interlayer insulating film 142. In some implementations, the width of the source contacts 164 and the through vias 166 may decrease closer to the upper insulating film 310.

The cell wiring structures 180 may be formed on the second interlayer insulating film 142. The cell wiring structures 180 may be electrically connected to the channel structures CH, the gate contacts 162, the source contacts 164, and/or the through vias 166. For example, a first inter-wiring insulating film 144 may be formed on the second interlayer insulating film 142. The cell wiring structures 180 may be formed within the first inter-wiring insulating film 144 and may thereby be connected to the channel structures CH, the gate contacts 162, the source contacts 164, and/or the through vias 166. The number of layers and the arrangement of the cell wiring structures 180 are merely example and not limited to the depiction.

The cell wiring structures 180 may include a conductive material, such as aluminum (Al), copper (Cu), W, Mo, Co, Ru, or an alloy thereof, but the present disclosure is not limited thereto. For example, the cell wiring structures 180 may include Cu wiring.

In some implementations, the cell wiring structures 180 may include the conductive lines 185, which are disposed in the cell array areas CA. The conductive lines 185 may extend longitudinally in the second direction Y. Moreover, the conductive lines 185 may be spaced apart from one another in the first direction X, extending in parallel in the second direction Y.

The conductive lines 185 may be electrically connected to the channel structures CH, which are arranged along the second direction Y. For example, the conductive lines 185 may be connected to the ends (e.g., the lower ends) of the semiconductor films 130 through the channel pads 136. The conductive lines 185 may be provided as bitlines (e.g., the bitlines BL of FIG. 8).

The source layer 300 may be formed on the second surface 102b of the first base insulating film 102. The source layer 300 may be electrically connected to the channel structures CH. For example, other ends (e.g., upper ends) of the semiconductor films 130 may be exposed from the data storage films 132 and may be connected to the source layer 300.

The source layer 300 may include a conductive material, for example, doped polysilicon, a metals, or a metal silicide, but the present disclosure is not limited thereto. For example, the source layer 300 may include polysilicon (poly-Si) doped with N-type impurities such as phosphorus (P) or arsenic (As). The source layer 300 may be provided as a common source line (e.g., the common source line CSL of FIG. 8).

In some implementations, the channel structures CH may protrude above the first base insulating film 102. For example, as illustrated in FIG. 12A, the other ends (e.g., the upper ends) of the semiconductor films 130 may be formed higher than the second surface 102b of the first base insulating film 102. The semiconductor films 130 can enhance the contact area with the source layer 300, thereby reducing contact resistance.

In some implementations, the cutting patterns WC may also protrude above the first base insulating film 102. As illustrated in FIG. 12A, the upper surfaces of the cutting patterns WC may be formed higher than the second surface 102b of the first base insulating film 102.

In some implementations, the source layer 300 may conformally extend along the profile of the protruding portions of the channel structures CH, the protruding portions of the cutting patterns WC, and the second surface 102b of the first base insulating film 102.

The upper insulating film 310 may be formed on the second surface 102b of the first base insulating film 102. The upper insulating film 310 may form an insulating area across the extension areas EA and the external area PA. The upper insulating film 310 may include, for example, at least one of silicon oxide, silicon nitride, and silicon oxynitride, but the present disclosure is not limited thereto. For example, the upper insulating film 310 may include a silicon oxide film.

The reflective structure 320 may be formed on the upper insulating film 310. The reflective structure 320 may be disposed in the extension areas EA and/or the external area PA. The reflective structure 320 may overlap with parts of the first and second stack structures SS1 and SS2 and first and second interlayer insulating films 141 and 142 in the extension areas EA and/or parts of the first and second interlayer insulating films 141 and 142 in the external area PA. The term “overlap” denotes an overlap in the third direction Z. The reflective structure 320 is illustrated as fully covering the extension areas EA and the external area PA, but the present disclosure is not limited thereto. In some implementations, the reflective structure 320 may be disposed in parts of the extension areas EA and/or part of the external area PA.

The reflective structure 320 may not be disposed in the cell array areas CA. For example, the reflective structure 320 may expose the first base insulating film 102, the channel structures CH, and the cutting patterns WC in the cell array areas CA. Additionally, the reflective structure 320 may not overlap with the first and second stack structures SS1 and SS2 and parts of the first and second interlayer insulating films 141 and 142 in the cell array area CA in the third direction Z.

The reflective structure 320 may include a DBR (Distributed Bragg Reflector). The reflective structure 320 may utilize Fresnel reflection enhancement interference to provide high reflectivity and low transmittance. The reflective structure 320 may have a multilayer structure where one or more first reflective layers 322 and one or more second reflective layers 324 with a different refractive index from the first reflective layers 322 are alternately stacked. For example, the first reflective layers 322 may include a material such as a silicon oxide film or a TEOS film, and the second reflective layer 324 may include a material such as a silicon nitride film or hafnium oxide film. In some implementations, the reflective structure 320 may include at least three pairs of first reflective layers 322 and second reflective layers 324.

To induce such constructive interference, a first thickness t₁ of the first reflective layers 22 and a second thickness t₂ of the second reflective layers 24 may be appropriately selected. The first thickness t₁ of the first reflective layers 22 within the range defined by Equation (1) above, and the second thickness t₂ of the second reflective layers 24 may be selected within the range defined by Equation (2) above. The reflective structure 320 may correspond to the reflective structure 20 of FIGS. 1 through 6, and thus, a detailed description thereof will be omitted.

In some implementations, the source layer 300 may extend further along at least part of the reflective structure 320. For example, the source layer 300 may extend further along the sides and the upper surface of the upper insulating film 310 and the reflective structure 320. That is, at least part of the reflective structure 320 may be interposed between the source layer 300 and the upper insulating film 310.

In some implementations, the reflective structure 320 may be interposed between the source layer 300 and the upper insulating film 310, in the extension areas EA. In some implementations, the source layer 300 may not be disposed within the external area PA.

In some implementations, the first reflective layer 322 may include a lowermost reflective layer disposed at a lowermost part of the reflective structure 320. For example, the bottom surface of the lowermost first reflective layer 322 disposed at the lowermost part of the reflective structure 320 may contact the upper insulating film 310.

In some implementations, the first reflective layer 322 may include an uppermost reflective layer disposed at an uppermost part of the reflective structure 320. For example, the upper surface of the uppermost first reflective layer 322 disposed at the uppermost part of the reflective structure 320 may contact the source layer 300.

The third interlayer insulating film 340 may be formed on the source layer 300, the reflective structure 320, and/or the upper insulating film 310. The third interlayer insulating film 340 may cover the source layer 300, the reflective structure 320, and/or the upper insulating film 310. The fourth interlayer insulating film 350 may be formed on the third interlayer insulating film 340. The third and fourth interlayer insulating films 340 and 350 may include, for example, at least one of silicon oxide, silicon nitride, silicon oxynitride, and a low-k material with a smaller dielectric constant than silicon oxide, but the present disclosure is not limited thereto.

The connection patterns 380 may be formed in the fourth interlayer insulating film 350. The connection patterns 380 may be electrically connected to the source contacts 164 and the source layer 300. For example, first contact pads 312, which are connected to the source contacts 164, may be formed in the upper insulating film 310. Additionally, first contact patterns 362, which connect the source layer 300 and the connection patterns 380 through the third interlayer insulating film 340, may be formed, and second contact patterns 364, which connect the first contact pads 312 and the connection patterns 380 through the reflective structure 320 and/or the third interlayer insulating film 340, may be formed.

The conductive pads 390 may be formed in the fourth interlayer insulating film 350, in the external area PA. The conductive pads 390 may be electrically connected to the through vias 166. For example, second contact pads 314, which are connected to the through vias 166, may be formed in the upper insulating film 310. Moreover, third contact patterns 366, which connect the second contact pads 314 and the conductive pads 390 through the reflective structure 320 and/or the third interlayer insulating film 340, may be formed.

The peripheral circuit structure PERI may include a peripheral circuit substrate 200, peripheral circuit elements PT, and peripheral circuit wiring structures 280. The peripheral circuit substrate 200 may include a semiconductor substrate, such as a Si, germanium (Ge), or silicon-germanium (SiGe) substrate. In some implementations, the peripheral circuit substrate 200 may include a silicon-on-insulator (SOI) or germanium-on-insulator (GOI) substrate.

The peripheral circuit elements PT may be formed on the peripheral circuit substrate 200. The peripheral circuit elements PT may form peripheral circuitry (e.g., the periphery circuitry 60 of FIG. 7), which controls the operation of the semiconductor memory device according to some embodiments of the present disclosure. For example, the peripheral circuit elements PT may include control logic (e.g., the control logic 67 of FIG. 7), a row decoder (e.g., the row decoder 63 of FIG. 7), and a page buffer (e.g., the page buffer 65 of FIG. 7). The surface of the peripheral circuit substrate 200 where the peripheral circuit elements PT are disposed may be referred to as the front side of the peripheral circuit substrate 200. Conversely, the surface of the peripheral circuit substrate 200 that is opposite to the front side of the peripheral circuit substrate 200 may be referred to as the back side of the peripheral circuit substrate 200.

The peripheral circuit elements PT may include, for example, transistors, but the present disclosure is not limited thereto. The peripheral circuit elements PT may include not only active elements, such as transistors, but also passive elements, such as capacitors, resistors, or inductors.

The peripheral circuit wiring structures 280 may be formed on the peripheral circuit elements PT. For example, a second inter-wiring insulating film 244 may be formed on the front side of the peripheral circuit substrate 200. The peripheral circuit wiring structures 280 may be formed in the second inter-wiring insulating film 244 and may be electrically connected to the peripheral circuit elements PT. The number of layers and the arrangement of the peripheral circuit wiring structures 280 are merely example and are not particularly limited.

In some implementations, the memory cell structure CELL may be stacked on the peripheral circuit structure PERI. For example, the memory cell structure CELL may be stacked on the second inter-wiring insulating film 244.

In some implementations, the first surface 102a of the first base insulating film 102 may face the peripheral circuit structure PERI. For example, the first and second stack structures SS1 and SS2 may be interposed between the source layer 300 and the peripheral circuit structure PERI.

In some implementations, the semiconductor device may have a chip-to-chip (C2C) structure. The C2C structure involves fabricating an upper chip including the memory cell structure CELL on a first wafer, fabricating a lower chip including the peripheral circuit structure PERI on a second wafer, which is different from the first wafer, and bonding the upper and lower chips together.

For example, the upper and lower chips may be bonded together by connecting first bonding metals 190 (and/or a first bonding insulating film 146) formed in the uppermost metal layer of the upper chip and second bonding metals 290 (and/or a second bonding insulating film 246) formed in the uppermost metal layer of the lower chip. For example, if the first bonding metals 190 and the second bonding metals 290 are formed of Cu, the upper and lower chips may be bonded in a Cu—Cu bonding method, but the present disclosure is not limited thereto. The first bonding metals 190 and the second bonding metals 290 may be formed of various other metals such as Al or W.

As the first bonding metals 190 and the second bonding metals 290 are bonded together, the cell wiring structures 180 may be electrically connected to the peripheral circuit wiring structures 280. Consequently, the memory cells formed in the cell array areas CA may be electrically connected to the peripheral circuit elements PT.

In the C2C structure, as the upper and lower chips are connected by bonding, the common source line (e.g., the source layer 300) of the upper chip may be disposed at the top of the semiconductor device.

Meanwhile, a laser annealing process may be performed on the common source line to activate the impurities included in the common source line. However, laser light used in the laser annealing process may penetrate areas with high laser transmittance (e.g., parts of the first and second interlayer insulating films 141 and 142 in the expansion areas EA and/or the external area PA) below the common source line, causing damage to the underlying multilayer metal wiring (e.g., the cell wiring structures 180 and the peripheral circuit wiring structures 280).

Conversely, the semiconductor device can prevent damage that may be caused by laser light to metal wiring, using the reflective structure 320. Specifically, as described above, the reflective structure 320 may be disposed to overlap in the third direction Z with the first and second interlayer insulating films 141 and 142, in the expansion areas EA and/or the external area PA. The reflective structure 320 can selectively block the laser light entering the expansion areas EA and/or the external area PA during the laser annealing process, thereby preventing damage to the cell wiring structures 180 and/or the peripheral circuit wiring structures 280. Accordingly, a semiconductor device with improved yield and reliability can be provided.

In FIGS. 11, 12B, and 12C, the first reflective layers 322 may include an uppermost first reflective layer 322t, which is disposed at the top of the reflective structure 320. For example, the upper surface of the uppermost first reflective layer 322t may contact the source layer 300. To ensure high reflectivity and low transmittance of the reflective structure 320, a third thickness t₃ of the uppermost first reflective layer 322t may be appropriately selected. In some implementations, the third thickness t₃ of the uppermost first reflective layer 322t may differ from the first thickness t₁. For example, as illustrated in FIG. 12B, the third thickness t₃ of the uppermost first reflective layer 322t may be less than the first thickness t₁. In some implementations, as illustrated in FIG. 12C, the third thickness t₃ of the uppermost first reflective layer 322t may be greater than the first thickness t₁.

In some implementations, the third thickness t₃ of the uppermost first reflective layer 322t may be selected within a range defined by Equation (3) below.

$$\frac{λ}{8 {n}_{3}} - Δ {t}_{3} \leq {t}_{3} \leq \frac{λ}{2 {n}_{3}} + Δ {t}_{3} ( where Δ {t}_{3} = \frac{λ}{10 {n}_{3}} ) \qquad ( 3 )$$

In Equation (3), λ represents the wavelength of light (or laser light) irradiated onto the reflective structure 320 during the laser annealing process for the source layer 300, and n₃ represents a third refractive index of the uppermost first reflective layer 322t.

For example, the wavelength A of the laser light used in the laser annealing process may be about 532 nm. At the wavelength 2, the third refractive index n₃ of the uppermost first reflective layer 322t, which includes a silicon oxide film, may be about 1.46. In this example, the third thickness t₃ of the uppermost first reflective layer 322t may range from about 9 nm to about 220 nm. Preferably, the third thickness t₃ of the uppermost first reflective layer 322t may range from about 40 nm to about 210 nm.

In some implementations, the third thickness t₃ of the uppermost first reflective layer 322t may range from about 40 nm to about 120 nm, or from about 190 nm to about 210 nm. In some implementations, the third thickness t₃ of the uppermost first reflective layer 322t may range from about 700 nm to about 900 nm.

In FIGS. 11 and 12D, the second reflective layers 324 include a lowermost reflective layer 324, which is disposed at the bottom of the reflective structure 320. For example, the bottom surface of the lowermost second reflective layer 324, disposed at the bottom of the reflective structure 320, may contact the upper insulating film 310.

In FIGS. 11 and 12E, the second reflective layers 324 include an uppermost second reflective layer 324t, which is disposed at the top of the reflective structure 320. For example, the upper surface of the uppermost second reflective layer 324t may contact the source layer 300. To ensure high reflectivity and low transmittance of the reflective structure 320, the thickness of the uppermost second reflective layer 324t may be appropriately selected. The uppermost second reflective layer 324t may be similar to the uppermost first reflective layer 322t of FIGS. 12B and 12C, and a detailed description thereof will be omitted.

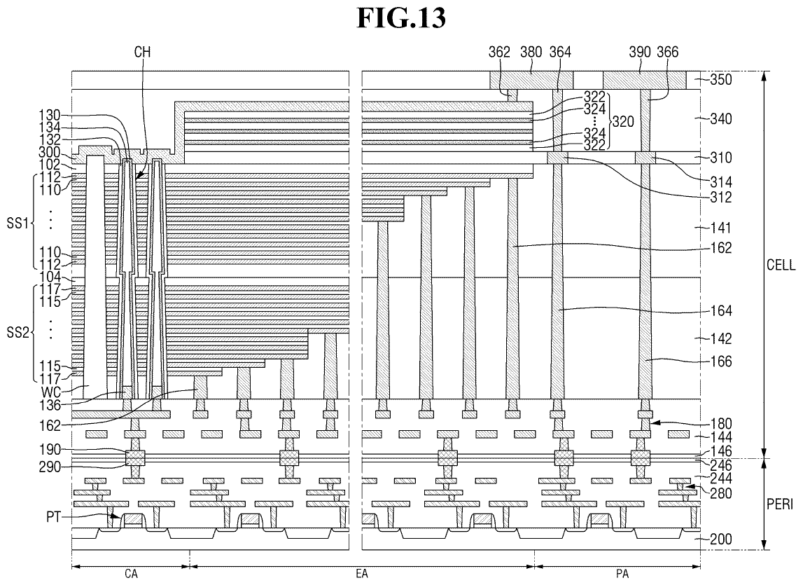

FIGS. 13 through 16 are cross-sectional views showing examples of semiconductor devices according to some implementations. For convenience, descriptions of content overlapping with what has been described above with reference to FIGS. 1 through 12 will be simplified or omitted.

In FIG. 13, a reflective structure 320 is not disposed in an external area PA. For example, the reflective structure 320 may expose part of an upper insulating film 310 in the external area PA. Moreover, the reflective structure 320 may not overlap with parts of first and second interlayer insulating films 141 and 142 in the external area PA in a third direction Z.

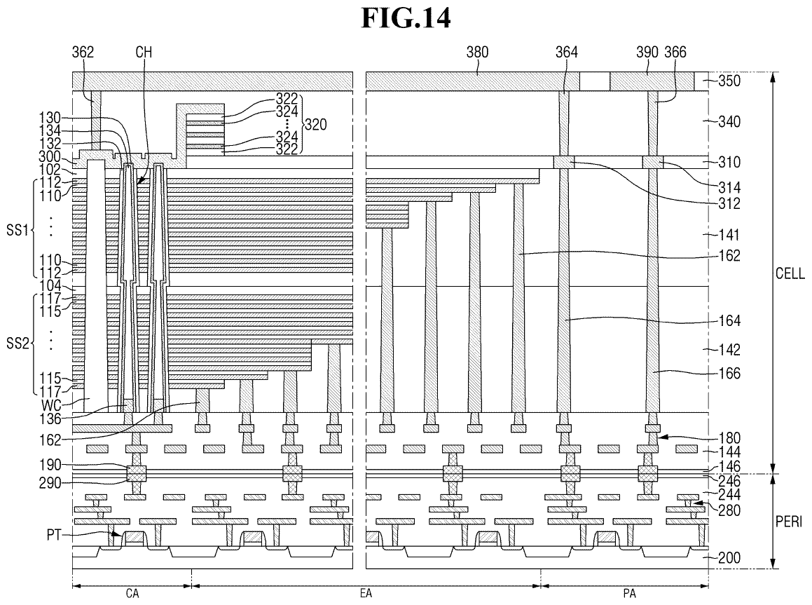

In FIG. 14, in some embodiments, a reflective structure 320 may be disposed in part of an expansion area EA. For example, the reflective structure 320 may expose part of an upper insulating film 310 in the expansion area EA. Additionally, the reflective structure 320 may not overlap with parts of first and second stack structures SS1 and SS2 and parts of first and second interlayer insulating films 141 and 142 in the expansion area EA in a third direction Z.

In some implementations, first contact patterns 362 may be disposed in a cell array area CA. The first contact patterns 362 may connect a source layer 300 of the cell array area CA and connection patterns 380 by penetrating a third interlayer insulating film 340.

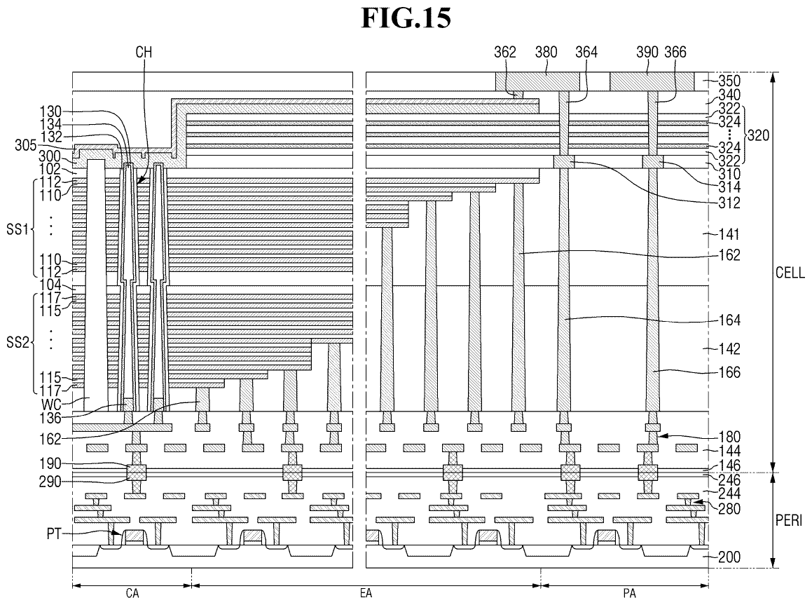

In FIG. 15, a conductive plate 305 may be further included. The conductive plate 305 may be formed on the source layer 300. For example, the conductive plate 305 may extend conformally along the upper surface of the source layer 300. The conductive plate 305 may be electrically connected to the source layer 300. The conductive plate 305 may include a conductive material, for example, a metal, such as W, Co, or Ni or a metal silicide, but the present disclosure is not limited thereto. The conductive plate 305 may be utilized to reduce the electrical resistance of a common source line (e.g., the common source line CSL of FIG. 8) including the source layer 300.

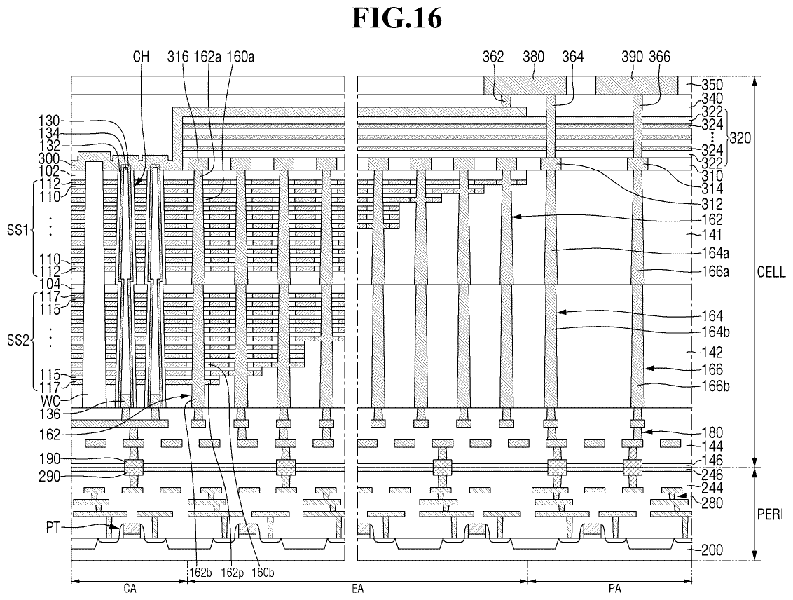

In FIG. 16, gate contacts 162 penetrate first and second stack structures SS1 and SS2. For example, a plurality of third contact pads 316 may be formed in an upper insulating film 310 in an expansion area EA. The gate contacts 162 may be electrically connected to the third contact pads 316, respectively, by penetrating the first and second stack structures SS1 and SS2. In some implementations, each of the gate contacts 162 may include a first through portion 162a, a second through portion 162b, and a protruding portion 162p.

The first through portions 162a may extend in a third direction Z to penetrate a first base insulating film 102, the first stack structure SS1, and a first interlayer insulating film 141. The second through portions 162b may be connected to the first through portions 162a by penetrating a second base insulating film 104, the second stack structure SS2, and a second interlayer insulating film 142. The protruding portions 162p may protrude from the sides of the first through portions 162a or the sides of the second through portions 162b to contact at least one of a plurality of gate electrodes (112 and 117). In some implementations, the protruding portions 162p may contact lowermost gate electrodes (hereinafter, the selected gate electrodes) disposed at the bottoms of the respective steps formed by the gate electrodes (112 and 117) in the expansion area EA.

Gate electrodes (112 and 117) other than the selected gate electrodes, i.e., non-selected gate electrodes, may be spaced apart from the gate contacts 162. For example, first insulating rings 160a can be formed between first gate electrodes 112 and each of the first through portions 162a, and second insulating rings 160b may be formed between second gate electrodes 117 and each of the second through portions 162b. The first insulating rings 160a or the second insulating rings 160b may be interposed between the gate contacts 162 and the non-selected gate electrodes and may not be interposed between the gate contacts 162 and the selected gate electrodes.

In some implementations, the gate contacts 162 may have a step difference between the first and second stack structures SS1 and SS2. For example, the width of the first through portions 162a may decrease closer to the third contact pads 316, and the width of the second through portions 162b may decrease closer to the first through portions 162a. Additionally, at the boundary between the first interlayer insulating film 141 and the second base insulating film 104, the width of the first through portions 162a may be greater than the width of the second through portions 162b.

In some implementations, source contacts 164 may have a step difference between the first and second stack structures SS1 and SS2. For example, the source contacts 164 may include third through portions 164a and fourth through portions 164b. The third through portions 164a may be connected to first contact pads 312 by penetrating the first interlayer insulating film 141. The fourth through portions 164b may be connected to the third through portions 164a by penetrating the second interlayer insulating film 142. The width of the third through portions 164a may decrease closer to the first contact pads 312, and the width of the fourth through portions 164b may decrease closer to the third through portions 164a. Additionally, at the boundary between the first and second interlayer insulating films 141 and 142, the width of the third through portions 164a may be greater than the width of the fourth through portions 164b.

In some implementations, through vias 166 may have a step difference between the first and second stack structures SS1 and SS2. For example, the through vias 166 may include fifth through portions 166a and sixth through portions 166b. The fifth through portions 166a may be connected to second contact pads 314 by penetrating the first interlayer insulating film 141. The sixth through portions 166b may be connected to the fifth through portions 166a by penetrating the second interlayer insulating film 142. The width of the fifth through portions 166a may decrease closer to the second contact pads 314, and the width of the sixth through portions 166b may decrease closer to the fifth through portions 166a. Additionally, at the boundary between the first and second interlayer insulating films 141 and 142, the width of the fifth through portions 166a may be greater than the width of the sixth through portions 166b.

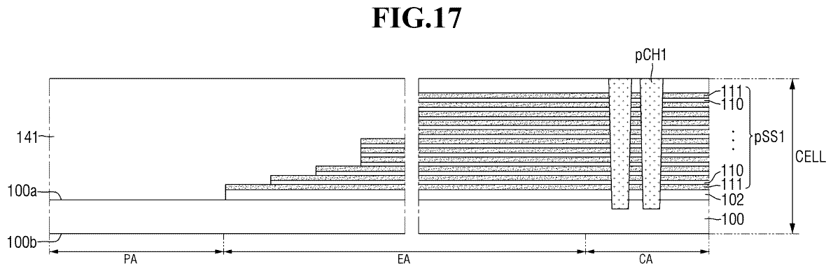

FIGS. 17 through 29 are cross-sectional views illustrating examples of intermediate steps of a method of fabricating a semiconductor device according to some implementations. For convenience, descriptions of content overlapping with what has been described so far with reference to FIGS. 1 through 16 will be simplified or omitted.

In FIG. 17, a first base insulating film 102, a first preliminary stack pSS1, and first preliminary channels pCH1 are formed on a base substrate 100. The base substrate 100 may include, for example, a semiconductor substrate, such as a Si substrate, a Ge substrate, or a SiGe substrate. Alternatively, the base substrate 100 may include a SOI substrate or a GOI substrate.

The base substrate 100 may include third and fourth surfaces 100a and 100b, which are opposite to each other. The third surface 100a may also be referred to as the front side of the base substrate 100, and the fourth surface 100b may also be referred to as the back side of the base substrate 100.

The first base insulating film 102 and the first preliminary stack pSS1 may be sequentially stacked on the third surface 100a of the base substrate 100. The first preliminary stack pSS1 may include a plurality of first mold insulating films 110 and a plurality of first mold sacrificial films 111, which are stacked on the first base insulating film 102 alternating with the first mold insulating films 110. The first mold sacrificial films 111 may include a material with an etch selectivity with respect to the first mold insulating films 110. For example, each of the first mold insulating films 110 may include a silicon oxide film, and each of the first mold sacrificial films 111 may include a silicon nitride film.

The first preliminary channels pCH1 may penetrate the first base insulating film 102 and the first preliminary stack pSS1. Additionally, the first preliminary channels pCH1 may be connected to the base substrate 100. For example, a first interlayer insulating film 141, which covers the first base insulating film 102 and the first preliminary stack pSS1, may be formed on the base substrate 100. The first preliminary channels pCH1 may penetrate the first interlayer insulating film 141, the first preliminary stack pSS1, and the first base insulating film 102 and may thereby be connected to the base substrate 100. In some implementations, the bottom surface of the first preliminary channels pCH1 may be formed lower than the third surface 100a of the base substrate 100.

The first preliminary channels pCH1 may include a material with an etch selectivity ratio with respect to the first mold insulating films 110 and the first mold sacrificial films 111. For example, the first preliminary channels pCH1 may include poly Si.

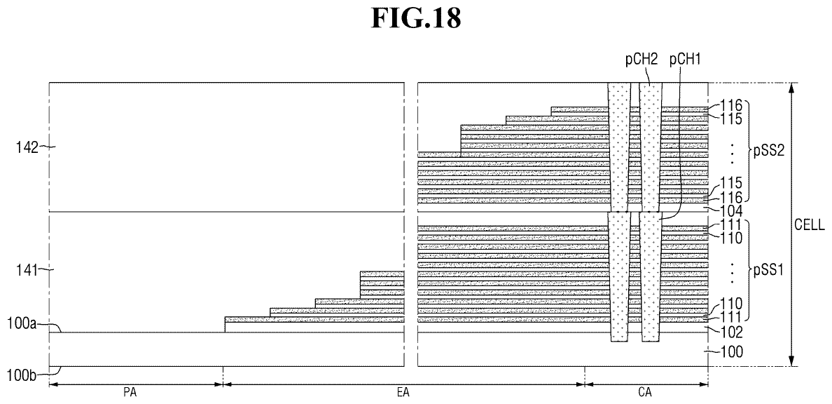

In FIG. 18, a second base insulating film 104, a second preliminary stack pSS2, and second preliminary channels pCH2 are formed on the first interlayer insulating film 141. The second base insulating film 104 and the second preliminary stack pSS2 may be sequentially stacked on the first interlayer insulating film 141. The second preliminary stack pSS2 may include a plurality of second mold insulating films 115 and a plurality of second mold sacrificial films 116, which are stacked on the second base insulating film 104 alternating with the second mold insulating films 115. The formation of the second preliminary stack pSS2 may be similar to the formation of the first preliminary stack pSS1, and a detailed description thereof will be omitted.

The second preliminary channels pCH2 may penetrate the second base insulating film 104 and the second preliminary stack pSS2. Additionally, the second preliminary channels pCH2 may be connected to the first preliminary channels pCH1. The formation of the second preliminary channels pCH2 may be similar to the formation of the first preliminary channels pCH1, and thus, a detailed description thereof will be omitted.

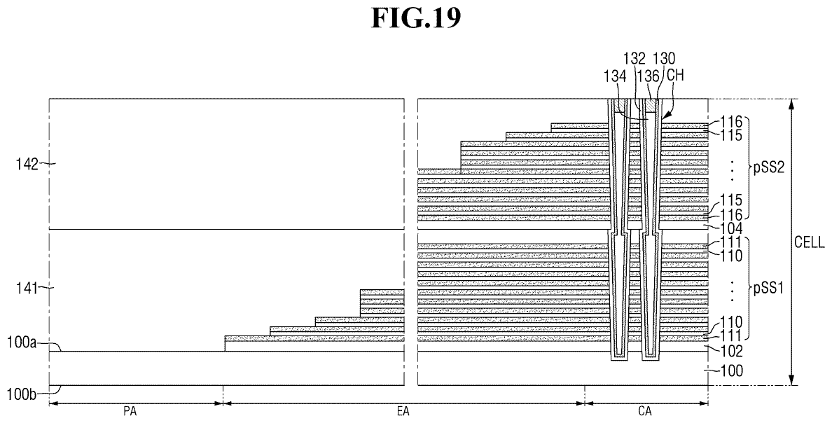

In FIG. 19, channel structures CH are formed. For example, the first preliminary channels pCH1 and the second preliminary channels pCH2 may be selectively removed. Thereafter, the channel structures CH may be formed in the areas from which the first preliminary channels pCH1 and the second preliminary channels pCH2 have been removed. In this manner, channel structures CH that penetrate the first and second preliminary stacks pSS1 and pSS2 and are connected to the base substrate 100 may be formed. In some implementations, the channel structures CH may include semiconductor films 130, data storage films 132, fill insulating films 134, and channel pads 136.

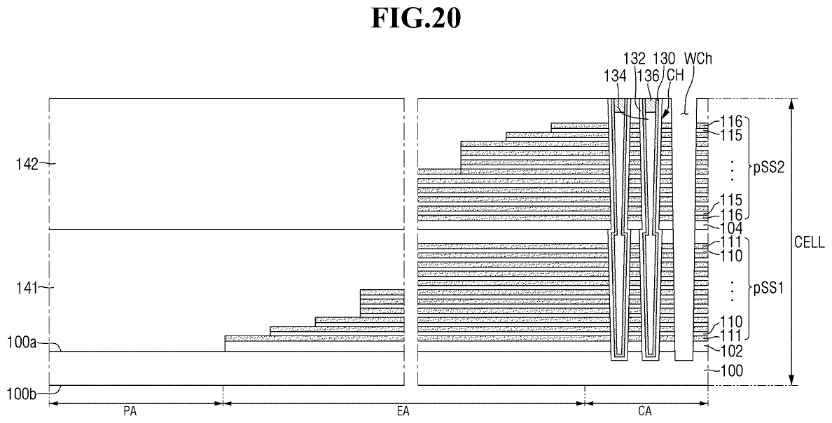

In FIG. 20, a cutting area WCh is formed. The cutting area WCh may extend in a first direction X and may cut the first and second preliminary stacks pSS1 and pSS2. In some implementations, the bottom surface of the cutting area WCh may be formed lower than the third surface 100a of the base substrate 100.

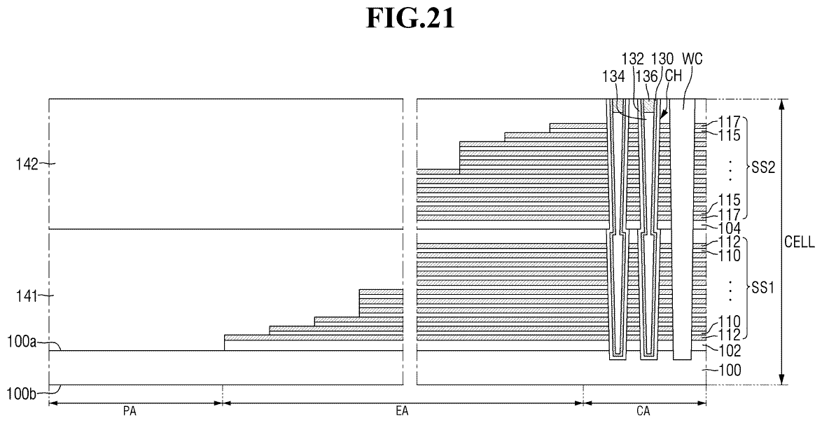

In FIG. 21, a plurality of gate electrodes (112 and 117) are formed. For example, mold sacrificial layers (111 and 116) exposed by the cutting area (WCh) may be selectively removed. Thereafter, the gate electrodes (112 and 117) may be formed in the areas from which the mold sacrificial layers (111 and 116) have been removed. Consequently, first and second stack structures SS1 and SS2 including mold insulating films (110 and 115) and the gate electrodes (112 and 117) may be formed. In some implementations, after the formation of the first and second stack structures SS1 and SS2, the cutting area WCh may be filled with an insulating material. As a result, a cutting pattern WC that cuts the first and second stack structures SS1 and SS2 may be formed.

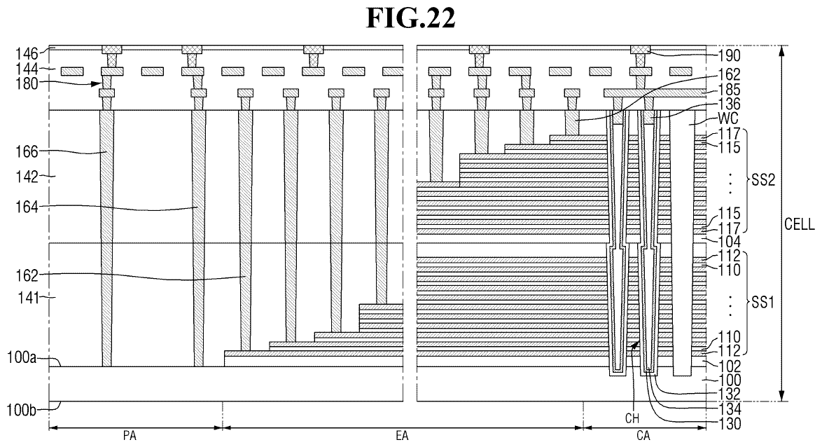

In FIG. 22, gate contacts 162, source contacts 164, through vias 166, a first inter-wiring insulating film 144, cell wiring structures 180, a first bonding insulating film 146, and first bonding metals 190 are formed. The gate contacts 162 may be disposed in an extension area EA. A plurality of gate contacts 162 may be connected to the corresponding gate electrodes (112 and 117) through the first and second interlayer insulating films 141 and 142.

The source contacts 164 and the through vias 166 may be disposed in an external area PA. The source contacts 164 and the through vias 166 may be connected to the base substrate 100 through the first and second interlayer insulating films 141 and 142.

The first inter-wiring insulating film 144 and the cell wiring structures 180 may be formed on the second interlayer insulating film 142. The cell wiring structures 180 may be electrically connected to the channel structures CH, the gate contacts 162, the source contacts 164, and/or the through vias 166.

The first bonding insulating film 146 and the first bonding metals 190 may be formed on the first inter-wiring insulating film 144. The first bonding metals 190 may be electrically connected to the cell wiring structures 180.

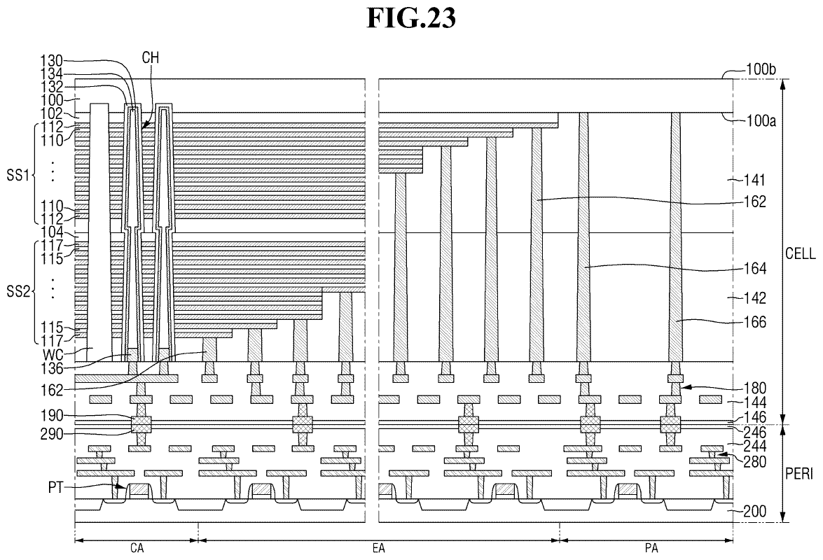

In FIG. 23, a memory cell structure CELL is stacked on a peripheral circuit structure PERI. In some implementations, the memory cell structure CELL may be stacked such that the third surface 100a of the base substrate 100 may face the peripheral circuit structure PERI. For example, the first bonding metals 190 and/or the first bonding insulating film 146 formed in the uppermost metal layer of the memory cell structure CELL may be bonded to second bonding metals 290 and/or a second bonding insulating film 246 formed in the uppermost metal layer of the peripheral circuit structure PERI.

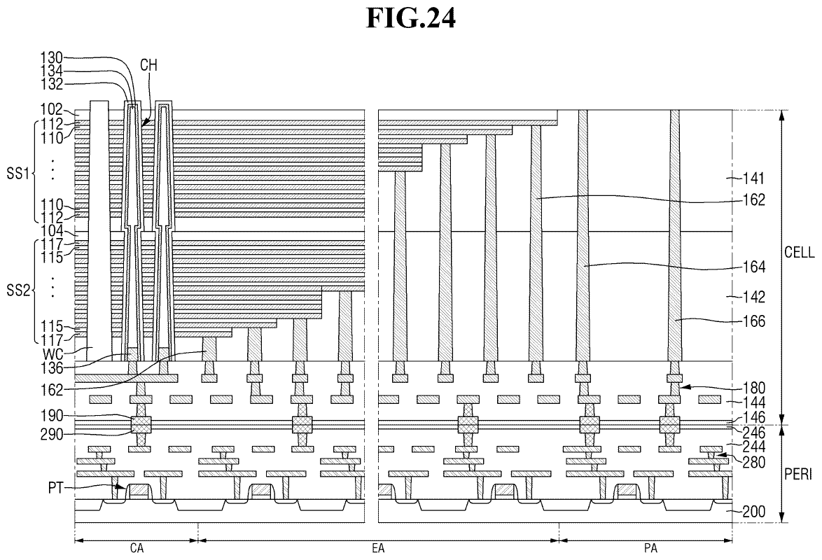

In FIG. 24, at least part of the base substrate 100 is removed. For example, a planarization process and/or a recess process may be performed on the fourth surface 100b of the base substrate 100. As a result, ends (e.g., upper ends) of the channel structures CH may be exposed.

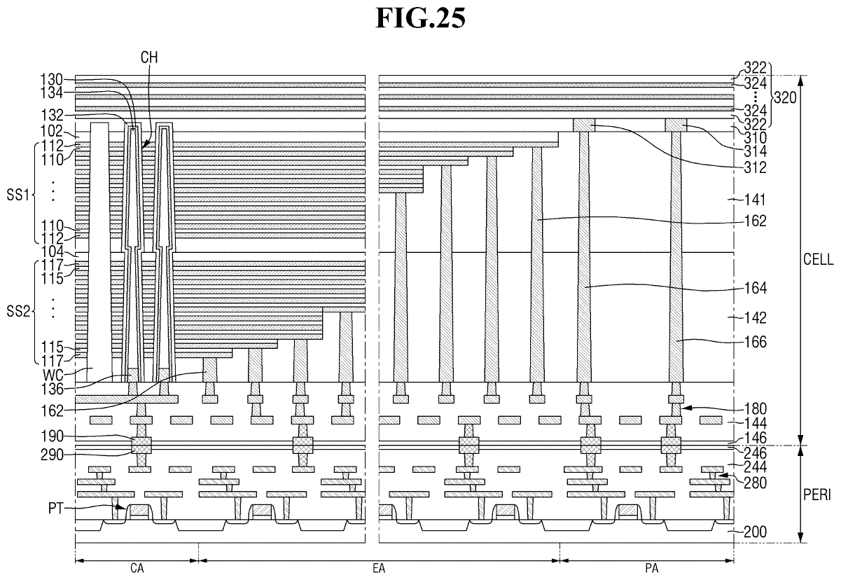

In FIG. 25, an upper insulating film 310, first contact pads 312, second contact pads 314, and a reflective structure 320 are formed on the first base insulating film 102 and the first interlayer insulating film 141. The upper insulating film 310 may cover the first base insulating film 102 and the first interlayer insulating film 141 across a cell array area CA, the extension area EA, and the external area PA. The first contact pads 312 and the second contact pads 314 may be formed in the upper insulating film 310. The first contact pads 312 may be connected to the source contacts 164, and the second contact pads 314 may be connected to the through vias 166.

The reflective structure 320 may cover the upper insulating film 310 across the cell array area CA, the extension area EA, and the external area PA. The reflective structure 320 may have a multilayer structure where one or more first reflective layers 322 and one or more second reflective layers 324 with a different refractive index from the first reflective layers 322 are alternately stacked. In some implementations, the reflective structure 320 may include at least three pairs of first reflective layers 322 and second reflective layers 324.

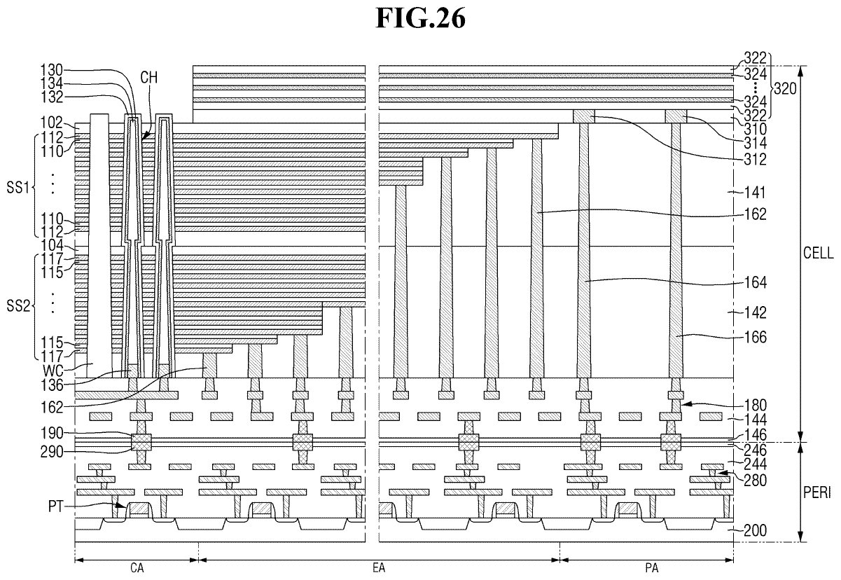

In FIG. 26, the upper insulating film 310 and the reflective structure 320 are patterned. For example, a photolithography process may be performed on the upper insulating film 310 and the reflective structure 320. The patterned upper insulating film 310 and the patterned reflective structure 320 may be disposed in the extension area EA and/or the external area PA, and may not be disposed within the cell array area CA. Consequently, the first base insulating film 102, the channel structures CH, and the cutting patterns WC may be exposed in the cell array area CA.

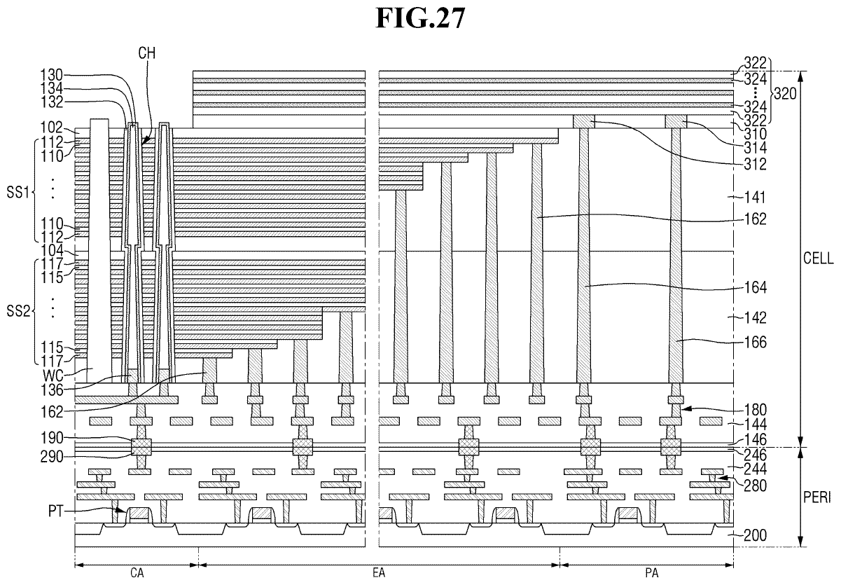

In FIG. 27, upper portions of the data storage films 132 are removed. For example, an etching process may be performed on the data storage films 132 of the exposed channel structures CH. As a result, the ends (e.g., the upper ends) of the semiconductor films 130 of the channel structures CH may be exposed.

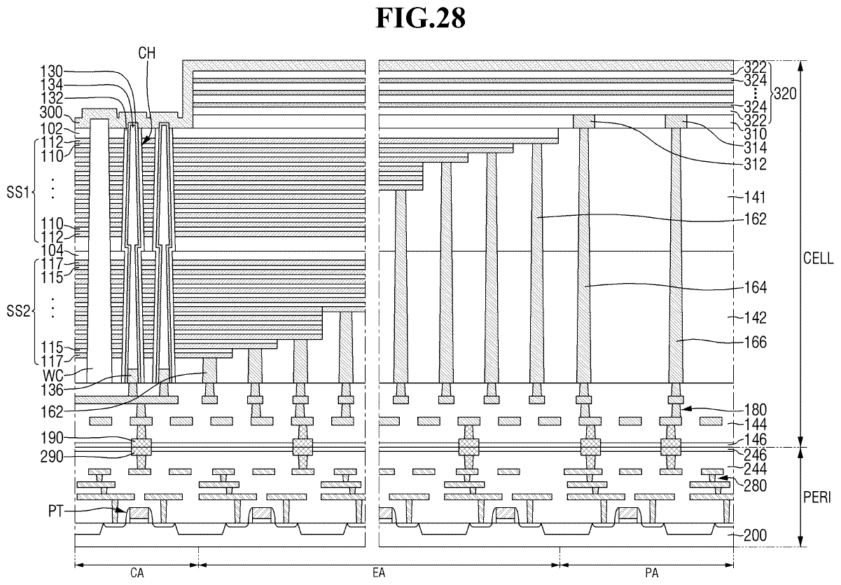

In FIG. 28, a source layer 300 is formed. The source layer 300 may be formed on the first base insulating film 102, the channel structures CH, the cutting patterns WC, and the reflective structure 320. In some implementations, the source layer 300 may extend conformally.

The source layer 300 may be connected to the ends (e.g., the upper ends) of the exposed semiconductor films 130. The source layer 300 may include a conductive material, for example, doped polysilicon, a metal, or a metal silicide, but the present disclosure is not limited thereto. For example, the source layer 300 may include poly-Si doped with N-type impurities, such as Por As.

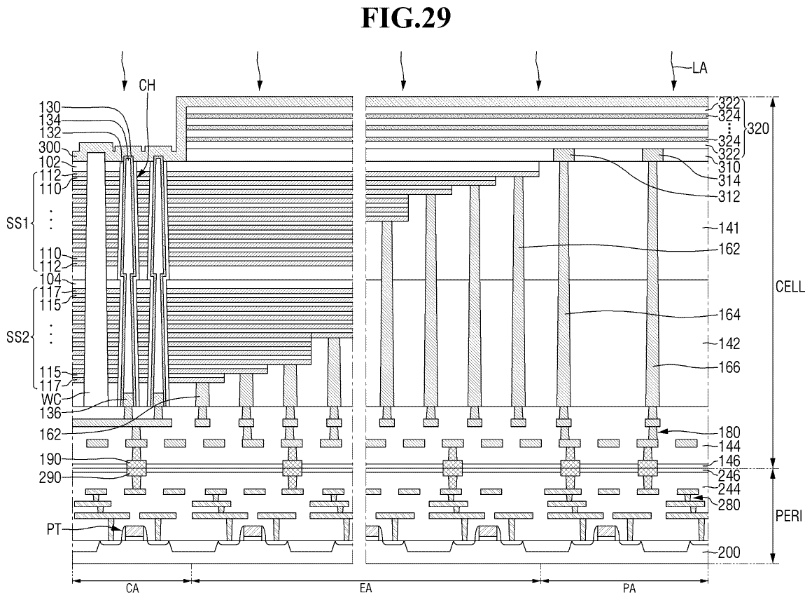

In FIG. 29, a laser annealing process LA is performed on the source layer 300. As the laser annealing process LA is performed, crystallization of the source layer 300 may be induced, or the impurities included in the source layer 300 may be activated. Unlike a general annealing process, the laser annealing process LA may be performed locally on the source layer 300, thereby minimizing damage to the semiconductor device.

Additionally, as mentioned above, the reflective structure 320 can selectively block laser light entering the expansion area EA and/or the external area PA during the laser annealing process LA, thereby preventing damage to the cell wiring structures 180 and/or the peripheral circuit wiring structures 280. Accordingly, a method of fabricating a semiconductor device with improved yield and reliability can be provided.

Thereafter, in FIG. 11, a patterning process for the source layer 300 is performed. Thereafter, a third interlayer insulating film 340, first contact patterns 362, second contact patterns 364, third contact patterns 366, a fourth interlayer insulating film 350, connection patterns 380, and conductive pads 390 may be formed on the patterned source layer 300. Accordingly, the semiconductor device of FIGS. 7 through 11 can be obtained.

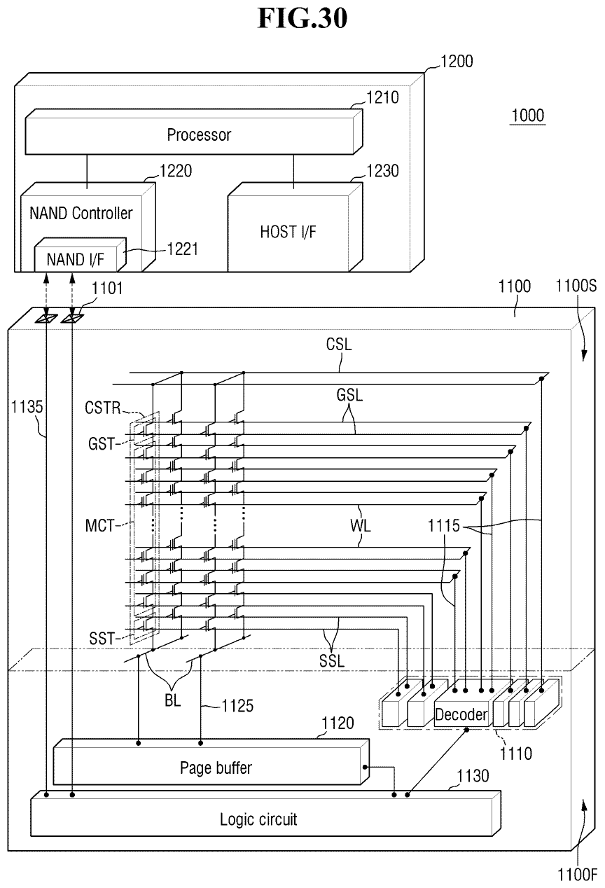

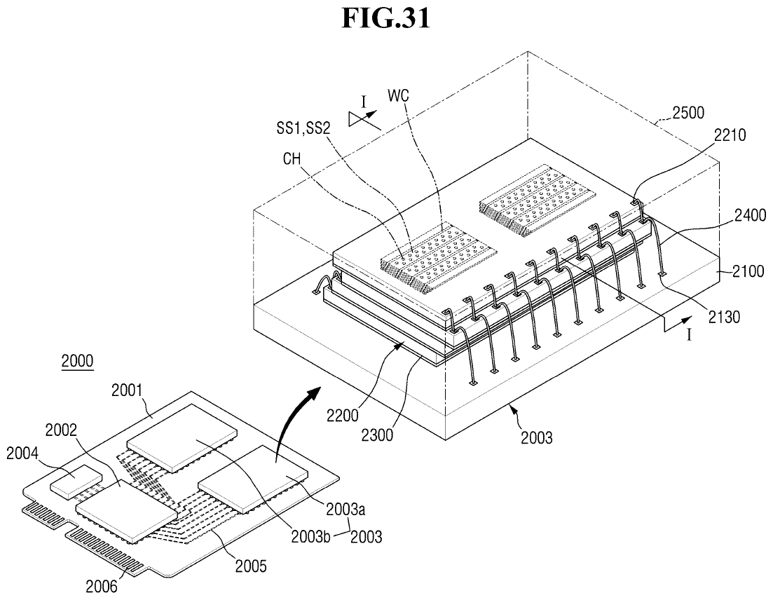

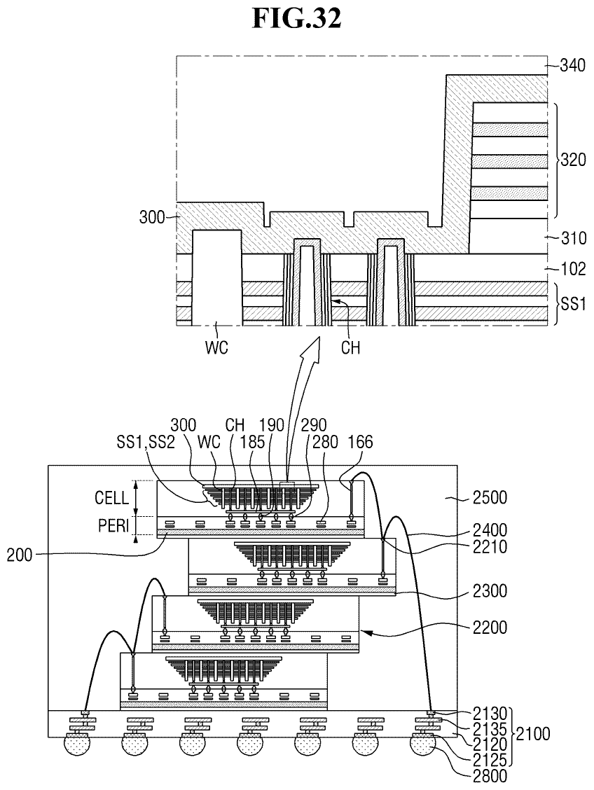

FIG. 30 is a block diagram showing an electronic system according to some implementations. FIG. 31 is a perspective view showing an example of an electronic system according to some implementations. FIG. 32 is a cross-sectional view taken along line I-I of FIG. 31 according to some implementations. For convenience, descriptions of content overlapping with what has been described with reference to FIGS. 1 through 29 will be simplified or omitted.

In FIG. 30, an electronic system 1000 may include a semiconductor memory device 1100 and a controller 1200, which is electrically connected to the semiconductor memory device 1100. The electronic system 1000 may be a storage device that includes at least one semiconductor memory device 1100 or an electronic device that includes a storage device. For example, the electronic system 1000 may be a solid-state drive (SSD) device, a universal serial bus (USB), a computing system, a medical device, or a communication device that includes at least one semiconductor memory device 1100.

The semiconductor memory device 1100 may be a non-volatile memory device (e.g., a NAND flash memory device) and may include, for example, at least one of the semiconductor devices depicted in FIGS. 7 through 16. The semiconductor memory device 1100 may include a first structure 1100F and a second structure 1100S on the first structure 1100F.

The first structure 1100F may be a peripheral circuit structure including a decoder circuit 1110 (e.g., the row decoder 63 of FIG. 7), a page buffer 1120 (e.g., the page buffer 65 of FIG. 7), and a logic circuit 1130 (e.g., the control logic 67 of FIG. 7). The first structure 1100F may correspond to, for example, the peripheral circuit structure PERI of any one of FIGS. 7 through 16.

The second structure 1100S may include a common source line CSL, a plurality of bitlines BL, and a plurality of cell strings CSTR, as described above with reference to FIG. 8. The cell strings CSTR may be connected to the decoder circuit 1110 through wordlines WL, one or more string select lines SSL, and one or more ground select lines GSL. Furthermore, the cell strings CSTR may be connected to the page buffer 1120 through the bitlines BL. The second structure 1100S may correspond to, for example, the memory cell structure CELL of any one of FIGS. 7 through 16.

In some implementations, the common source line CSL and the cell strings CSTR may be electrically connected to the decoder circuit 1110 through first connection wires 1115, which extend from the first structure 1100F to the second structure 1100S.

In some implementations, the bitlines BL may be electrically connected to the page buffer 1120 through second connection wires 1125.

The semiconductor memory device 1100 may communicate with the controller 1200 through input/output pads 1101, which are electrically connected to the logic circuit 1130 (e.g., the control logic 67 of FIG. 7). The input/output pads 1101 may correspond to the conductive pads 390 of any one of FIGS. 7 through 16. The input/output pads 1101 may be electrically connected to the logic circuit 1130 through input/output connection wires 1135, which extend from the first structure 1100F to the second structure 1100S. The connection wires 1135 may correspond to, for example, the through vias 166 of any one of FIGS. 7 through 16.

The controller 1200 may include a processor 1210, a NAND controller 1220, and a host interface 1230. In some implementations, the electronic system 1000 may include a plurality of semiconductor memory devices 1100, in which case, the controller 1200 may control the plurality of semiconductor memory devices 1100.

The processor 1210 may control the operation of the entire electronic system 1000 that includes the controller 1200. The processor 1210 may operate in accordance with specific firmware and may control the NAND controller 1220 to access the semiconductor memory device 1100. The NAND controller 1220 may include the NAND interface 1221, which processes communication with the semiconductor memory device 1100. Control commands for controlling the semiconductor memory device 1100, data to be written to memory cell transistors MCT of the semiconductor memory device 1100, and data to be read from the memory cell transistors MCT of the semiconductor memory device 1100 may be transmitted through the NAND interface 1221. The host interface 1230 may provide communication capabilities between the electronic system 1000 and an external host. In response to receiving control commands from the external host through the host interface 1230, the processor 1210 may control the semiconductor memory device 1100.

In FIGS. 31 and 32, an electronic system 2000 may include a main substrate 2001 and a main controller 2002, one or more semiconductor packages 2003, and a DRAM 2004, which are mounted on the main substrate 2001. The semiconductor packages 2003 and the DRAM 2004 may be connected to the main controller 2002 via wiring patterns 2005, which are formed on the main substrate 2001.

The main substrate 2001 may include a connector 2006, which includes a plurality of pins to be coupled to the external host. The number and arrangement of the pins in the connector 2006 may vary depending on the communication interface between the electronic system 2000 and the external host. In some implementations, the electronic system 2000 may communicate with the external host according to one of the following interfaces: USB, PCI-Express, SATA, and M-Phy for UFS. In some implementations, the electronic system 2000 may operate on power supplied by the external host through the connector 2006. The electronic system 2000 may further include a power management integrated circuit (PMIC), which distributes the power supplied from the external host to the main controller 2002 and the semiconductor packages 2003.

The main controller 2002 may write data to the semiconductor packages 2003 or read data from the semiconductor packages 2003. The main controller 2002 may improve the operating speed of the electronic system 2000.

The DRAM 2004 may serve as a buffer memory to mitigate the speed difference between the semiconductor packages 2003, which are data storage spaces, and the external host. The DRAM 2004, which is included in the electronic system 2000, may function as a cache memory and may provide a temporary storage space for control operations for the semiconductor packages 2003. If the electronic system 2000 includes the DRAM 2004, the main controller 2002 may further include a DRAM controller for controlling the DRAM 2004, in addition to a NAND controller for controlling the semiconductor packages 2003.

The semiconductor packages 2003 may include first and second semiconductor packages 2003a and 2003b, which are spaced apart from each other. The first and second semiconductor packages 2003a and 2003b may both be semiconductor packages that include a plurality of semiconductor chips 2200. Each of the first and second semiconductor packages 2003a and 2003b may include a package substrate 2100, semiconductor chips 2200, which are on the package substrate 2100, adhesive layers 2300, which are disposed on the bottom surfaces of the semiconductor chips 2200, connection structures 2400, which electrically connect the semiconductor chips 2200 and the package substrate 2100, and a molding layer 2500, which covers the semiconductor chips 2200 and the connection structures 2400 on the package substrate 2100.

The package substrate 2100 may be a PCB including package upper pads 2130. Each of the semiconductor chips 2200 may include input/output pads 2210. The input/output pads 2210 may correspond to the input/output pads 1101 of FIG. 30.

In some implementations, the connection structures 2400 may be bonding wires that electrically connect the input/output pads 2210 and the package upper pads 2130. Accordingly, in each of the first and second semiconductor packages 2003a and 2003b, the semiconductor chips 2200 may be electrically connected to one another through bonding wires and may also be electrically connected to the package upper pads 2130 of the package substrate 2100. In some implementations, the semiconductor chips 2200 in each of the first and second semiconductor packages 2003a and 2003b may be electrically connected to one another through connection structures that include through silicon vias (TSVs), rather than through the connection structures 2400, which are bonding wires.

In some implementations, the main controller 2002 and the semiconductor chips 2200 may be included within a single package. In some implementations, the main controller 2002 and the semiconductor chips 2200 may be mounted on a separate interposer substrate from the main substrate 2001, and may be connected to one another by wires formed on the interposer substrate.

In some implementations, the package substrate 2100 may be a PCB. The package substrate 2100 may include a package substrate body 2120, package upper pads 2130, which are disposed on the upper surface of the package substrate body 2120, lower pads 2125, which are disposed on or exposed through the bottom surface of the package substrate body 2120, and internal wires 2135, which are electrically connected the upper pads 2130 and the lower pads 2125 within the package substrate body 2120. The upper pads 2130 may be electrically connected to the connection structures 2400. The lower pads 2125 may be connected to the wiring patterns 2005 of the main substrate 2001 of the electronic system 2000 through conductive connectors 2800, as illustrated in FIG. 31.

In the electronic system 2000, each of the semiconductor chips 2200 may include any one of the semiconductor devices depicted in FIGS. 7 through 16. For example, each of the semiconductor chips 2200 may include a memory cell structure CELL and a peripheral circuit structure PERI. For example, the memory cell structure CELL may include a first stack structure SS1, a second stack structure SS2, channel structures CH, cutting patterns WC, through vias 166, cell wiring structures 180, a source layer 300, an upper insulating film 310, and a reflective structure 320, as depicted in FIGS. 7 through 16. The peripheral circuit structure PERI may include a peripheral circuit substrate 200 and peripheral circuit wiring structures 280. The memory cell structure CELL and the peripheral circuit structure PERI may be bonded to each other through first bonding metals 190 and second bonding metals 290.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A semiconductor device comprising:
a source layer;
a stack structure including a plurality of gate electrodes, each being sequentially stacked on the source layer and spaced apart from one another in a first direction;
an interlayer insulating film covering the stack structure;
a channel structure extending in the first direction extending into the stack structure in a first area and connected to the source layer in the first area; and
a reflective structure overlapping in the first direction with the interlayer insulating film in a second area that is around the first area,
wherein the reflective structure includes one or more first reflective layers, each having a first refractive index, and one or more second reflective layers, each being stacked alternating with the one or more first reflective layers in the first direction and having a second refractive index that is different from the first refractive index.

2. The semiconductor device of claim 1, wherein the reflective structure does not overlap with the stack structure in the first area.

3. The semiconductor device of claim 1, wherein at least part of the reflective structure is interposed between the source layer in the second area and the interlayer insulating film in the second area.

4. The semiconductor device of claim 1, wherein the reflective structure includes at least three pairs of the first reflective layers and the second reflective layers.

5. The semiconductor device of claim 1,
wherein the first refractive index is smaller than the second refractive index, and
wherein a first thickness of the one or more first reflective layers is greater than a second thickness of the one or more second reflective layers.

6. The semiconductor device of claim 5,
wherein the one or more first reflective layers comprise a silicon oxide film, and
wherein the one or more second reflective layers comprise a silicon nitride film.

7. The semiconductor device of claim 1, wherein a first thickness t₁ of the one or more first reflective layers is selected from a range defined by Equation (1), and a second thickness t₂ of the one or more second reflective layers is selected from ranges defined by Equation (2):
$$\frac{λ}{4 {n}_{2}} - Δ {t}_{1} \leq {t}_{1} \leq \frac{λ}{4 {n}_{1}} + Δ {t}_{1} ( where Δ {t}_{1} = \frac{1}{10} ( \frac{λ}{4 {n}_{1}} ) ) \qquad ( 1 )$$
$$\frac{λ}{4 {n}_{2}} - Δ {t}_{2} \leq {t}_{2} \leq \frac{λ}{4 {n}_{2}} + Δ {t}_{2} ( where Δ {t}_{2} = \frac{1}{10} ( \frac{λ}{4 {n}_{2}} ) ) \qquad ( 2 )$$
wherein λ represents a wavelength of light irradiated onto the reflective structure, n₁ represents the first refractive index, and n₂ represents the second refractive index.

8. The semiconductor device of claim 7,
wherein the one or more first reflective layers include an uppermost reflective layer disposed at an uppermost part of the reflective structure, and
wherein a third thickness t₃ of the uppermost reflective layer is selected from a range defined by Equation (3):
$$\frac{λ}{8 {n}_{3}} - Δ {t}_{3} \leq {t}_{3} \leq \frac{λ}{2 {n}_{3}} + Δ {t}_{3} ( where Δ {t}_{3} = \frac{λ}{10 {n}_{3}} ) \qquad ( 3 )$$
wherein λ represents the wavelength of the light irradiated onto the reflective structure, and n₃ represents a refractive index of the uppermost reflective layer.

9. The semiconductor device of claim 1, wherein the source layer includes a polysilicon film doped with impurities.

10. The semiconductor device of claim 1,
wherein the channel structure includes a semiconductor film that extends in the first direction intersecting the plurality of gate electrodes, and a data storage film interposed between the semiconductor film and the plurality of gate electrodes, and
wherein an end of the semiconductor film contacts the source layer.

11. The semiconductor device of claim 1, further comprising:
a peripheral circuit structure comprising a peripheral circuit substrate and a peripheral circuit element on the peripheral circuit substrate,
wherein the stack structure is interposed between the source layer and the peripheral circuit structure.

12. A semiconductor device comprising:
a peripheral circuit structure including a peripheral circuit substrate and a peripheral circuit element on the peripheral circuit substrate; and
a memory cell structure stacked on the peripheral circuit structure, the memory cell structure comprising a first area and a second area around the first area,
wherein the memory cell structure includes:
a base insulating film that has a first surface that faces the peripheral circuit structure and a second surface that is opposite to the first surface;
a stack structure that is on the first surface of the base insulating film and comprises a plurality of gate electrodes that are sequentially stacked and spaced apart from one another;
an interlayer insulating film that covers the stack structure;
a source layer that is on the second surface of the base insulating film;
a channel structure that intersects the plurality of gate electrodes in the first area and is connected to the source layer in the first area; and
a reflective structure that is interposed between the source layer in the second area and the interlayer insulating film in the second area, and
wherein the reflective structure includes one or more first reflective layers that have a first refractive index and a first thickness, and one or more second reflective layers that are stacked alternating with the one or more first reflective layers and have a second refractive index that is different from the first refractive index.

13. The semiconductor device of claim 12, wherein the reflective structure is not interposed between the source layer in the first area and the stack structure in the first area.

14. The semiconductor device of claim 13,
wherein the first refractive index is smaller than the second refractive index, and
wherein the first thickness of the one or more first reflective layers is greater than a second thickness of the one or more second reflective layers.

15. The semiconductor device of claim 14,
wherein the one or more first reflective layers comprise a silicon oxide film, and
wherein the one or more second reflective layers comprise a silicon nitride film.

16. The semiconductor device of claim 15,
wherein the first thickness is 82 nm to 100 nm, and
wherein the second thickness is 60 nm to 72 nm.

17. The semiconductor device of claim 14,
wherein the one or more first reflective layers comprise an uppermost reflective layer disposed at an uppermost part of the reflective structure, and
wherein the uppermost reflective layer has a third thickness that is different from the first thickness.

18. The semiconductor device of claim 17,
wherein the one or more first reflective layers comprise a silicon oxide film,
wherein the one or more second reflective layers comprise a silicon nitride film,
wherein the first thickness is 82 nm to 100 nm,
wherein the second thickness is 60 nm to 72 nm, and
wherein the third thickness is 40 nm to 210 nm.

19. The semiconductor device of claim 12, wherein the source layer comprises a polysilicon film doped with impurities.

20. The semiconductor device of claim 12, wherein the reflective structure includes at least three pairs of the first reflective layers and the second reflective layers.

21-31. (canceled)
